(19) United States
(12) Patent Application Publication
(10) Pub. No.: US 2025/0364343 A1
(43) Pub. Date: Nov. 27, 2025

(54) REINFORCED STRUCTURE WITH CAPPING LAYER

(71) Applicant: Taiwan Semiconductor Manufacturing Company Limited, Hsinchu (TW)

(72) Inventors: Jing-Ye Juang, Hsinchu CIty (TW); Hsien-Wei Chen, Hsinchu CIty (TW); Chia-Ling Lu, Tainan City (TW); Shin-Puu Jeng, Po-Shan Village (TW)

(21) Appl. No.: 19/286,373

(22) Filed: Jul. 31, 2025

Related U.S. Application Data
(62) Division of application No. 17/829,534, filed on Jun. 1, 2022.

(51) Int. Cl. H01L 23/31; H01L 21/48; H01L 21/56; H01L 23/00; H01L 23/498; H01L 25/065

(52) U.S. Cl. CPC H01L 23/3135; H01L 21/4817; H01L 21/565; H01L 23/49833; H01L 24/16; H01L 24/32; H01L 24/73; H01L 25/0655; H01L 23/49811; H01L 23/49816; H01L 23/49822; H01L 23/49838; H01L 25/0657; H01L 2224/16227; H01L 2224/16238; H01L 2224/32225; H01L 2224/73204; H01L 2225/06513; H01L 2225/06524; H01L 2924/1431; H01L 2924/1437; H01L 2924/1611; H01L 2924/1616; H01L 2924/16195; H01L 2924/16235; H01L 2924/16251; H01L 2924/16724; H01L 2924/16747; H01L 2924/16787; H01L 2924/182; H01L 2924/3511; H01L 2924/35121

(57) ABSTRACT

A disclosed semiconductor structure may include an interposer, a first semiconductor die electrically coupled to the interposer, a packaging substrate electrically coupled to the interposer, and a capping layer covering one or more of a first surface of the first semiconductor die and a second surface of the packaging substrate. The capping layer may be formed over respective surfaces of each of the first semiconductor die and the packaging substrate. In certain embodiments, the capping layer may be formed only on the first surface of the first semiconductor die and not formed over the package substrate. In further embodiments, the semiconductor structure may include a second semiconductor die, such that the capping layer covers a surface of only one of the first semiconductor die and the second semiconductor die. The semiconductor structure may include a molding compound die frame that is partially or completely covered by the capping layer.

### RELATED APPLICATION

This application is a divisional of U.S. patent application Ser. No. 17/829,534 entitled “Reinforced Structure With Capping Layer And Methods Of Forming The Same” filed Jun. 1, 2022, the entire contents of which are hereby incorporated by reference for all purposes.

### BACKGROUND

Interfaces between a fan-out wafer level package (FOWLP) and an underfill material portion are subjected to mechanical stress during subsequent handling of an assembly of the FOWLP, the underfill material portion, and a packaging substrate, such as the mechanical stress associated with attaching the packaging substrate to a printed circuit board (PCB). In addition, interfaces between a FOWLP and an underfill material portion are subjected to mechanical stress during use within a computing device, such as when a mobile device is accidently dropped to cause a mechanical shock during usage. Cracks may be formed in the underfill material, and may induce additional cracks in a semiconductor die, solder material portions, interposers, and/or various dielectric layers within a semiconductor die or within a packaging substrate. Thus, suppression of the formation of cracks in the underfill material and other package components is desired.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a region of an exemplary structure that includes a first carrier substrate and interposers, according to various embodiments.

FIG. 1B is a top-down view of the region of the exemplary structure of FIG. 1A, according to various embodiments.

FIG. 2A is vertical cross-sectional view of a region of a further exemplary structure after formation of redistribution-side bonding structures and first solder material portions, according to various embodiments.

FIG. 2B is a top-down view of the region of the exemplary structure of FIG. 2A, according to various embodiments.

FIG. 3A is a vertical cross-sectional view of a region a further exemplary structure after attaching semiconductor dies, according to various embodiments.

FIG. 3B is a top-down view of the region of the exemplary structure of FIG. 3A, according to various embodiments.

FIG. 3C is a magnified vertical cross-sectional view of a high bandwidth memory die, according to various embodiments.

FIG. 4 is a vertical cross-sectional view of a region of a further exemplary structure after formation of die-side underfill material portions, according to various embodiments.

FIG. 5A is a vertical cross-sectional view of a region of a further exemplary structure after formation of an epoxy molding compound (EMC) matrix, according to various embodiments.

FIG. 5B is a top-down view of the region of the exemplary structure of FIG. 5A, according to various embodiments.

FIG. 6 is a vertical cross-sectional view of a region of a further exemplary structure after attaching a second carrier substrate and detaching the first carrier substrate, according to various embodiments.

FIG. 7 is a vertical cross-sectional view of a region of a further exemplary structure after formation of interposer bonding pads, according to various embodiments.

FIG. 8 is a vertical cross-sectional view of a region of a further exemplary structure after detaching the second carrier substrate, according to various embodiments.

FIG. 9 is a vertical cross-sectional view of a region of a further exemplary structure during dicing of a redistribution substrate and the EMC matrix, according to various embodiments.

FIG. 10A is a vertical cross-sectional view of a fan-out package, according to various embodiments.

FIG. 10B is a horizontal cross-sectional view of the fan-out package along the horizontal plane B-B′ of FIG. 10A, according to various embodiments.

FIG. 11A is a vertical cross-sectional view of a packaging substrate, according to various embodiments.

FIG. 11B is a top-down view of the packaging substrate of FIG. 11A, according to various embodiments.

FIG. 12 is a vertical cross-sectional view of a further exemplary structure after attaching the fan-out package to the packaging substrate, according to various embodiments.

FIG. 13A is a vertical cross-sectional view of a further exemplary structure after formation of an underfill material portion, according to various embodiments.

FIG. 13B is a horizontal cross-sectional view of the exemplary structure along the horizontal plane B-B′ of FIG. 13A, according to various embodiments.

FIG. 14A is a vertical cross-sectional view of a further exemplary structure in which thermal stresses may cause mechanical degradation, according to various embodiments.

FIG. 14B is a vertical cross-sectional view of an enlarged portion of the exemplary structure of FIG. 14A illustrating thermally induced deformations, according to various embodiments.

FIG. 14C is a top view of a portion of the exemplary structure of FIG. 14A showing thermally induced cracking, according to various embodiments.

FIG. 14D is a top view of a further portion of the exemplary structure of FIG. 14A showing thermally induced cracking, according to various embodiments.

FIG. 14E is a vertical cross-sectional view of a portion of the exemplary structure of FIG. 14A showing thermally induced delamination, according to various embodiments.

FIG. 14F is a vertical cross-sectional view of a further portion of the exemplary structure of FIG. 14A showing thermally induced delamination and cracking, according to various embodiments.

FIG. 15A is a vertical cross-sectional view of a further exemplary structure including a capping layer that may mitigate thermally-induced mechanical degradation, according to various embodiments.

FIG. 15B is a vertical cross-sectional view of an enlarged portion of the exemplary structure of FIG. 15A illustrating a portion of the capping layer, according to various embodiments.

FIG. 15C is a top view of a portion of the exemplary structure of FIG. 15A showing a portion of the capping layer, according to various embodiments.

FIG. 15D is a top view of a further portion of the exemplary structure of FIG. 15A showing a respective further portion of the capping layer, according to various embodiments.

FIG. 15E is a vertical cross-sectional view of a portion of the exemplary structure of FIG. 15A showing a side view of a portion of the capping layer, according to various embodiments.

FIG. 15F is a vertical cross-sectional view of a further portion of the exemplary structure of FIG. 15A showing a side view of a respective further portion of the capping layer, according to various embodiments.

FIG. 16A is a vertical cross-sectional view of the exemplary structure of FIG. 15A showing further details of the capping layer, according to various embodiments.

FIG. 16B is top view of the exemplary structure of FIGS. 15A and 16A, according to various embodiments.

FIG. 16C is a vertical cross-sectional view of an enlarged portion of the capping layer, according to various embodiments.

FIG. 17A is a vertical cross-sectional view of a further exemplary structure having a capping layer formed only over a fan-out package, according to various embodiments.

FIG. 17B is a top view of the exemplary structure of FIG. 17A, according to various embodiments.

FIG. 18A is a vertical cross-sectional view of a further exemplary structure having a capping layer only over a portion of the fan-out package, according to various embodiments.

FIG. 18B is a top view of the exemplary structure of FIG. 18A, according to various embodiments.

FIG. 19A is a vertical cross-sectional view of a further exemplary structure having a capping layer and a pinning structure, according to various embodiments.

FIG. 19B is a top view of the exemplary structure of FIG. 19A, according to various embodiments.

FIG. 20A is a vertical cross-sectional view of a further exemplary structure having a capping layer only on the fan-out package 500, according to various embodiments.

FIG. 20B is a top view of the exemplary structure of FIG. 20A, according to various embodiments.

FIG. 21A is a vertical cross-sectional view of an intermediate structure that may be used in the formation of a semiconductor structure having a capping layer, according to various embodiments.

FIG. 21B is a vertical cross-sectional view of a further intermediate structure that may be used in the formation of a semiconductor structure having a capping layer, according to various embodiments.

FIG. 21C is a vertical cross-sectional view of a further intermediate structure that may be used in the formation of a semiconductor structure having a capping layer, according to various embodiments.

FIG. 21D is a vertical cross-sectional view of a further intermediate structure that may be used in the formation of a semiconductor structure having a capping layer, according to various embodiments.

FIG. 21E is a vertical cross-sectional view of a semiconductor structure having a capping layer, according to various embodiments.

FIG. 22A is a vertical cross-sectional view of an intermediate structure that may be used in the formation of a fan-out package having a capping layer, according to various embodiments.

FIG. 22B is a vertical cross-sectional view of a further intermediate structure that may be used in the formation of a fan-out package having a capping layer, according to various embodiments.

FIG. 22C is a vertical cross-sectional view of a further intermediate structure that may be used in the formation of a fan-out package having a capping layer, according to various embodiments.

FIG. 22D is a vertical cross-sectional view of a further intermediate structure that may be used in the formation of a fan-out package having a capping layer, according to various embodiments.

FIG. 22E is a vertical cross-sectional view of a further intermediate structure that may be used in the formation of a fan-out package having a capping layer, according to various embodiments.

FIG. 22F is a vertical cross-sectional view of a further intermediate structure that may be used in the formation of a fan-out package having a capping layer, according to various embodiments.

FIG. 22G is a vertical cross-sectional view of a further intermediate structure that may be used in the formation of a fan-out package having a capping layer, according to various embodiments.

FIG. 22H is a vertical cross-sectional view of a further intermediate structure that may be used in the formation of a fan-out package having a capping layer, according to various embodiments.

FIG. 22I is a vertical cross-sectional view of a further intermediate structure that may be used in the formation of a fan-out package having a capping layer, according to various embodiments.

FIG. 22J is a vertical cross-sectional view of a further intermediate structure that may be used in the formation of a fan-out package having a capping layer, according to various embodiments.

FIG. 22K is a vertical cross-sectional view of a fan-out package having a capping layer, according to various embodiments.

FIG. 23 is a flowchart illustrating operations of a method of forming a semiconductor structure having a capping layer, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to semiconductor devices, and particularly to chip package structures such as a FOWLP and a fan-out panel level package (FOPLP). While this disclosure is described using an FOWLP configuration, the various embodiment methods and structures of this disclosure may be implemented in an FOPLP configuration or any other fan-out package configuration. Fan-out packages are subject to deformation under stress during subsequent assembly processes and/or during operation under mechanical stress and/or under heat. According to an aspect of this disclosure, deformation of a fan-out package may be reduced by forming a capping layer over one or more components of the semiconductor package structure.

Typically, heterogeneous integration is used to integrate a large interposer (such as a CoWoS® interposer or an organic interposer) and a high electrical performance substrate, such as a multi-layer core or a multilayer substrate (which may include 12 or more layers) for a high performance chip. The effective coefficient of thermal expansion for such a structure may be more than four times the coefficient of thermal expansion for silicon. Such a large mismatch of coefficients of thermal expansion between a substrate and semiconductor dies on an interposer may often result in molding crack at fan-out module corners. For these reasons, large fan-out modules formed by molding may be at high crack risk at the corners.

Disclosed embodiments may mitigate the occurrence of cracking, delamination, and other mechanical degradation by providing a capping layer that may counteract thermally-induced stress/strains that may otherwise cause damage. Accordingly, a disclosed semiconductor structure may include an interposer, a first semiconductor die electrically coupled to the interposer, a packaging substrate electrically coupled to the interposer, and a capping layer covering one or more of a first surface of the first semiconductor die and a second surface of the packaging substrate. The capping layer may be formed over respective surfaces of each of the first semiconductor die and the packaging substrate. In certain embodiments, the capping layer may be formed only on the first surface of the first semiconductor die and not formed over the package substrate. In further embodiments, the semiconductor structure may include a second semiconductor die, such that the capping layer covers a surface of only one of the first semiconductor die and the second semiconductor die. The semiconductor structure may include a molding compound die frame that is partially or completely covered by the capping layer.

In a further embodiment, a semiconductor structure may be provided that includes an interposer, a semiconductor die electrically coupled to the interposer, a molding compound die frame, and a capping layer that forms a continuous structure covering respective surfaces of the semiconductor die, the molding compound die frame, and the interposer. The capping layer may include one or more of stainless steel, copper, nickel, tungsten, aluminum, magnalium, titanium, silver, and gold. The capping layer may further include a seed layer and a bulk layer. The seed layer may include one or more of stainless steel, TiCu, TiW, TiN, and TaN, and the bulk layer may include one or more of stainless steel, copper, nickel, tungsten, aluminum, magnalium, titanium, silver, and gold.

In a further embodiment, a method of forming a semiconductor structure may include attaching a semiconductor die to an interposer such that the semiconductor die is electrically coupled to the interposer, and forming a molding compound die frame in contact with the semiconductor die and the interposer that may provide mechanical support to the semiconductor die and the interposer. The method may further include forming a capping layer that may cover respective surfaces of the semiconductor die and the molding compound die frame. The method may further include forming the capping layer as a continuous structure that covers respective surfaces of the semiconductor die, the molding compound die frame, and the interposer. The method may further include attaching the interposer to a packaging substrate such that the interposer is electrically coupled to the packaging substrate, and forming the capping layer as a continuous structure covering respective surfaces of the semiconductor die, the molding compound die frame, and the packaging substrate.

Various embodiments disclosed herein may effectively reduce the impact of the molding stress, and may mitigate the formation of molding cracks, delamination, and other mechanical degradation, thereby providing enhanced reliability to the interposer and the package substrate. The various aspects and embodiments of the methods and structures of this disclosure are described with reference to accompanying drawings herein below.

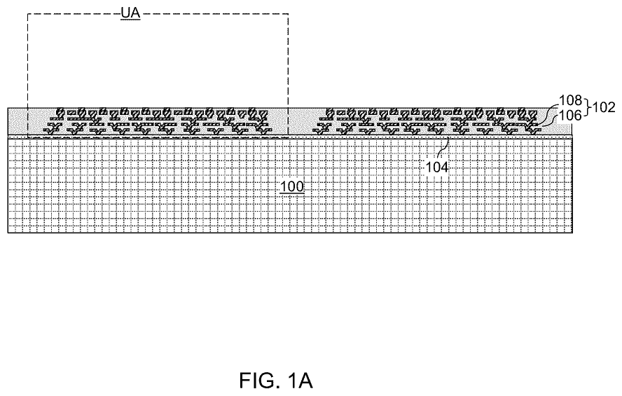

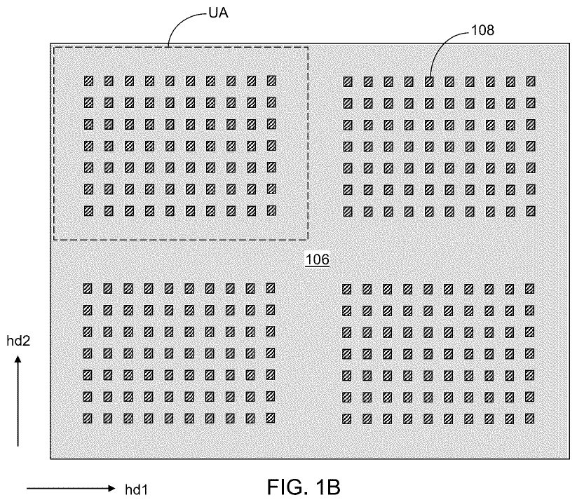

Referring to FIGS. 1A and 1B, a first exemplary structure according to an embodiment of this disclosure may include a first carrier substrate 100 and interposers 102 formed on a front side surface of the first carrier substrate 100. The first carrier substrate 100 may include an optically transparent substrate such as a glass substrate or a sapphire substrate. The diameter of the first carrier substrate 100 may be in a range from 150 mm to 290 mm, although lesser and greater diameters may be used. In addition, the thickness of the first carrier substrate 100 may be in a range from 500 microns to 2,000 microns, although lesser and greater thicknesses may also be used. Alternatively, the first carrier substrate 100 may be provided in a rectangular panel format. The dimensions of the first carrier in such alternative embodiments may be substantially the same.

A first adhesive layer 104 may be applied to the front-side surface of the first carrier substrate 100. In one embodiment, the first adhesive layer 104 may be a light-to-heat conversion (LTHC) layer. The LTHC layer may be a solvent-based coating applied using a spin coating method. The LTHC layer may convert ultraviolet light to heat, which may cause the material of the LTHC layer to lose adhesion. Alternatively, the first adhesive layer 104 may include a thermally decomposing adhesive material. For example, the first adhesive layer 104 may include an acrylic pressure-sensitive adhesive that decomposes at an elevated temperature. The debonding temperature of the thermally decomposing adhesive material may be in a range from 150 degrees to 200 degrees Celsius.

Redistribution structures may be formed over the first adhesive layer 104. Specifically, an interposer 102 may be formed within each unit area UA, which is the area of a repetition unit that may be repeated in a two-dimensional array over the first carrier substrate 100. Each interposer 102 may include redistribution dielectric layers 106 and redistribution wiring interconnects 108. The redistribution dielectric layers 106 include a respective dielectric polymer material such as polyimide (PI), benzocyclobutene (BCB), or polybenzobisoxazole (PBO). Other suitable materials may be within the contemplated scope of disclosure. Each redistribution dielectric layer 106 may be formed by spin coating and drying of the respective dielectric polymer material. The thickness of each redistribution dielectric layer 106 may be in a range from 2 microns to 40 microns, such as from 4 microns to 20 microns. Each redistribution dielectric layer 106 may be patterned, for example, by applying and patterning a respective photoresist layer thereabove, and by transferring the pattern in the photoresist layer into the redistribution dielectric layer 106 using an etch process such as an anisotropic etch process. The photoresist layer may be subsequently removed, for example, by ashing.

Each of the redistribution wiring interconnects 108 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 400 nm, and the copper seed layer may have a thickness in a range from 100 nm to 500 nm. The metallic fill material for the redistribution wiring interconnects 108 may include copper, nickel, or copper and nickel. Other suitable metallic fill materials are within the contemplated scope of disclosure. The thickness of the metallic fill material that is deposited for each redistribution wiring interconnect 108 may be in a range from 2 microns to 40 microns, such as from 4 microns to 10 microns, although lesser or greater thicknesses may also be used. The total number of levels of wiring in each interposer 102 (i.e., the levels of the redistribution wiring interconnects 108) may be in a range from 1 to 10. A periodic two-dimensional array (such as a rectangular array) of interposers 102 may be formed over the first carrier substrate 100. Each interposer 102 may be formed within a unit area UA. The layer including all interposers 102 is herein referred to as an interposer layer. The interposer layer includes a two-dimensional array of interposers 102. In one embodiment, the two-dimensional array of interposers 102 may be a rectangular periodic two-dimensional array of interposers 102 having a first periodicity along a first horizontal direction hd1 and having a second periodicity along a second horizontal direction hd2 that is perpendicular to the first horizontal direction hd1.

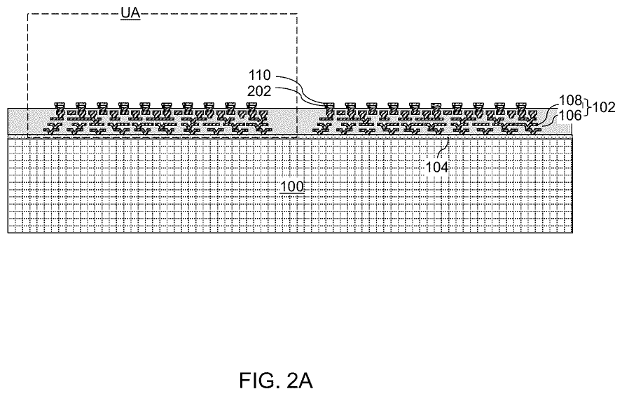

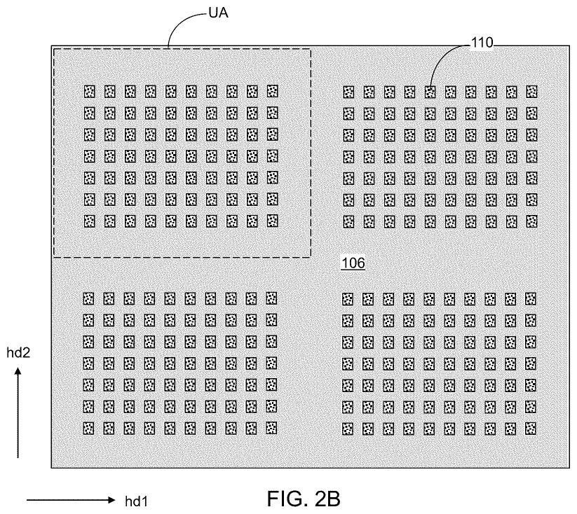

Referring to FIGS. 2A and 2B, at least one metallic material and a first solder material may be sequentially deposited over the front-side surface of the interposers 102. The at least one metallic material includes a material that may be used for metallic bumps, such as copper. The thickness of the at least one metallic material may be in a range from 5 microns to 60 microns, such as from 10 microns to 30 microns, although lesser and greater thicknesses may also be used. The first solder material may include a solder material suitable for C2 bonding, i.e., for microbump bonding. The thickness of the first solder material may be in a range from 2 microns to 30 microns, such as from 4 microns to 15 microns, although lesser and greater thicknesses may also be used.

The first solder material and the at least one metallic material may be patterned into discrete arrays of first solder material portions 110 and arrays of metal bonding structures, which are herein referred to as arrays of redistribution-side bonding structures 202. Each array of redistribution-side bonding structures 202 is formed within a respective unit area UA. Each array of first solder material portions 110 is formed within a respective unit area UA. Each first solder material portion 110 may have a same horizontal cross-sectional shape as an underlying redistribution-side bonding structures 202.

In one embodiment, the redistribution-side bonding structures 202 may include, and/or may consist essentially of, copper or a copper-containing alloy. Other suitable materials are within the contemplated scope of disclosure. The thickness of the redistribution-side bonding structures 202 may be in a range from 5 microns to 60 microns, although lesser or greater thicknesses may also be used. The redistribution-side bonding structures 202 may have horizontal cross-sectional shapes of rectangles, rounded rectangles, circles, regular polygons, irregular polygons, or any other two-dimensional curvilinear shape having a closed periphery. In one embodiment, redistribution-side bonding structures 202 may be configured for microbump bonding (i.e., C2 bonding), and may have a thickness in a range from 10 microns to 30 microns, although lesser or greater thicknesses may also be used. In this embodiment, each array of redistribution-side bonding structures 202 may be formed as an array of microbumps (such as copper pillars) having a lateral dimension in a range from 10 microns to 25 microns, and having a pitch in a range from 20 microns to 50 microns.

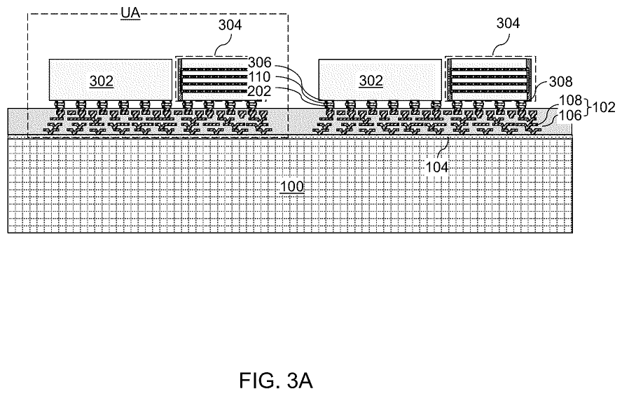

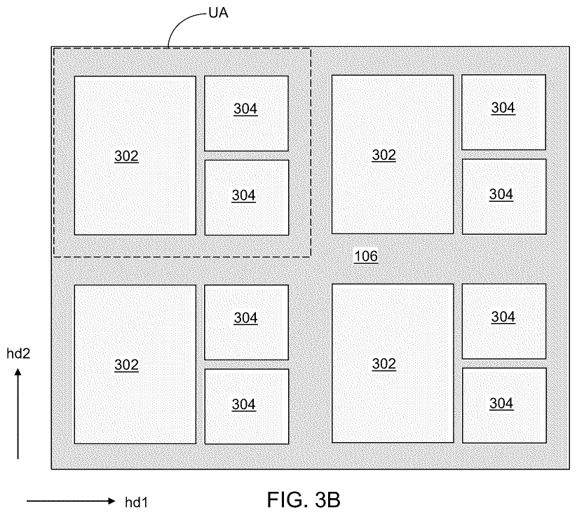

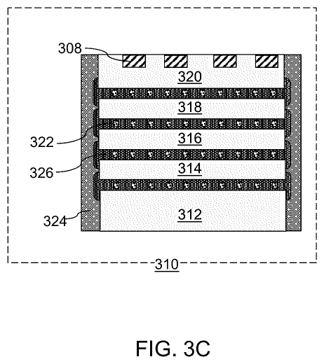

Referring to FIGS. 3A and 3B, a set of at least one semiconductor die (302, 304) may be bonded to each interposer 102. In one embodiment, the interposers 102 may be arranged as a two-dimensional periodic array, and multiple sets of at least one semiconductor die (302, 304) may be bonded to the interposers 102 as a two-dimensional periodic rectangular array of sets of the at least one semiconductor die (302, 304). Each set of at least one semiconductor die (302, 304) includes at least one semiconductor die. Each set of at least one semiconductor die (302, 304) may include any set of at least one semiconductor die known in the art. In one embodiment, each set of at least one semiconductor die (302, 304) may include a plurality of semiconductor dies (302, 304). For example, each set of at least one semiconductor die (302, 304) may include at least one system-on-chip (SoC) die 302 and/or at least one memory die 304. Each SoC die 302 may include an application processor die, a central processing unit die, or a graphic processing unit die. In one embodiment, the at least one memory die 304 may include a high bandwidth memory (HBM) die that includes a vertical stack of static random access memory dies. In one embodiment, the at least one semiconductor die (302, 304) may include at least one system-on-chip (SoC) die and a high bandwidth memory (HBM) die including a vertical stack of static random access memory (SRAM) dies that are interconnected to one another through microbumps and are laterally surrounded by an epoxy molding material enclosure frame.

Each semiconductor die (302, 304) may include a respective array of die-side bonding structures (306, 308). For example, each SoC die 302 may include an array of SoC metal bonding structures 306, and each memory die 304 may include an array of memory-die metal bonding structures 308. Each of the semiconductor dies (302, 304) may be positioned in a face-down position such that die-side bonding structures (306, 308) face the first solder material portions 110. Each set of at least one semiconductor die (302, 304) may be placed within a respective unit area UA. Placement of the semiconductor dies (302, 304) may be performed using a pick and place apparatus such that each of the die-side bonding structures (306, 308) may be placed on a top surface of a respective one of the first solder material portions 110.

Generally, an interposer 102 including redistribution-side bonding structures 202 thereupon may be provided, and at least one semiconductor die (302, 304) including a respective set of die-side bonding structures (306, 308) may be provided. The at least one semiconductor die (302, 304) may be bonded to the interposer 102 using first solder material portions 110 that are bonded to a respective redistribution-side bonding structure 202 and to a respective one of the die-side bonding structures (306, 308). Each set of at least one semiconductor die (302, 304) may be attached to a respective interposer 102 through a respective set of first solder material portions 110.

Referring to FIG. 3C, a high bandwidth memory (HBM) die 310 is illustrated, which may be used as a memory die 304 within the first exemplary structures of FIGS. 3A and 3B. The HBM die 310 may include a vertical stack of static random access memory dies (312, 314, 316, 318, 320) that are interconnected to one another through microbumps 322 and are laterally surrounded by an epoxy molding material enclosure frame 324. The gaps between vertically neighboring pairs of the random access memory dies (312, 314, 316, 318, 320) may be filled with a HBM underfill material portions 326 that laterally surrounds a respective set of microbumps 322. The HBM die 310 may include an array of memory-die metal bonding structures 308 configured to be bonded to a subset of an array of redistribution-side bonding structures 202 within a unit area UA. The HBM die 310 may be configured to provide a high bandwidth as defined under JEDEC standards, i.e., standards defined by The JEDEC Solid State Technology Association.

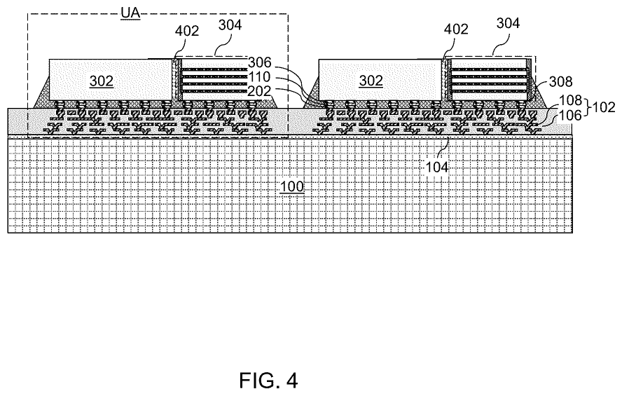

Referring to FIG. 4, a die-side underfill material may be applied into each gap between the interposers 102 and sets of at least one semiconductor die (302, 304) that are bonded to the interposers 102. The die-side underfill material may include any underfill material known in the art. A die-side underfill material portion 402 may be formed within each unit area UA between an interposer 102 and an overlying set of at least one semiconductor die (302, 304). The die-side underfill material portions 402 may be formed by injecting the die-side underfill material around a respective array of first solder material portions 110 in a respective unit area UA. Any known underfill material application method may be used, which may be, for example, the capillary underfill method, the molded underfill method, or the printed underfill method.

Within each unit area UA, a die-side underfill material portion 402 may laterally surround, and contact, each of the first solder material portions 110 within the unit area UA. The die-side underfill material portion 402 may be formed around, and contact, the first solder material portions 110, the redistribution-side bonding structures 202, and the die-side bonding structures (306, 308) in the unit area UA.

Each interposer 102 in a unit area UA includes redistribution-side bonding structures 202. At least one semiconductor die (302, 304) including a respective set of die-side bonding structures (306, 308) is attached to the redistribution-side bonding structures 202 through a respective set of first solder material portions 110 within each unit area UA. Within each unit area UA, a die-side underfill material portion 402 laterally surrounds the redistribution-side bonding structures 202 and the die-side bonding structures (306, 308) of the at least one semiconductor die (302, 304).

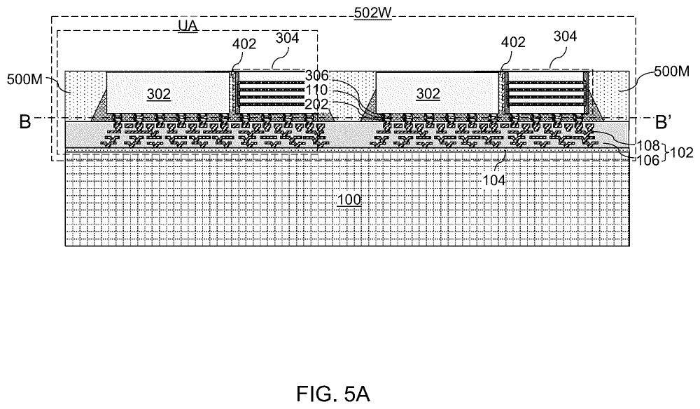

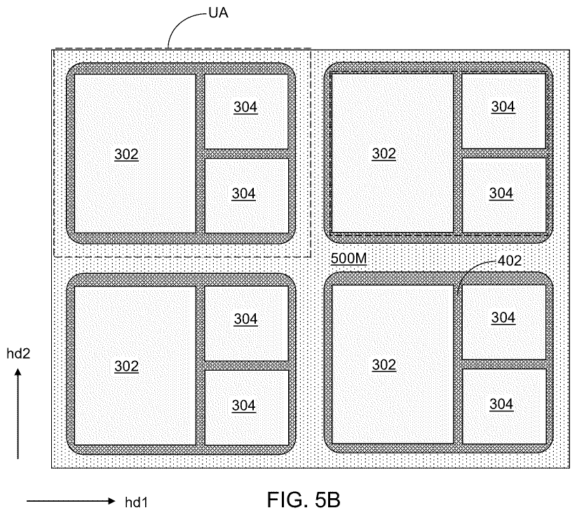

Referring to FIGS. 5A and 5B, an epoxy molding compound (EMC) may be applied to the gaps between contiguous assemblies of a respective set of semiconductor dies (302, 304) and a die-side underfill material portion 402.

The EMC may include an epoxy-containing compound that may be hardened (i.e., cured) to provide a dielectric material portion having sufficient stiffness and mechanical strength. The EMC may include epoxy resin, hardener, silica (as a filler material), and other additives. The EMC may be provided in a liquid form or in a solid form depending on the viscosity and flowability. Liquid EMC provides better handling, good flowability, less voids, better fill, and less flow marks. Solid EMC provides less cure shrinkage, better stand-off, and less die drift. A high filler content (such as 85% in weight) within an EMC may shorten the time in mold, lower the mold shrinkage, and reduce the mold warpage. Uniform filler size distribution in the EMC may reduce flow marks, and may enhance flowability. The curing temperature of the EMC may be lower than the release (debonding) temperature of the first adhesive layer 104 in embodiments in which the adhesive layer includes a thermally debonding material. For example, the curing temperature of the EMC may be in a range from 125° C. to 150° C.

The EMC may be cured at a curing temperature to form an EMC matrix 500M that laterally surrounds and embeds each assembly of a set of semiconductor dies (302, 304) and a die-side underfill material portion 402. The EMC matrix 500M includes a plurality of epoxy molding compound (EMC) die frames that may be laterally adjoined to one another. Each EMC die frame is a portion of the EMC matrix 500M that is located within a respective unit area UA. Thus, each EMC die frame laterally surrounds and embeds a respective a set of semiconductor dies (302, 304) and a respective die-side underfill material portion 402. Young's modulus of pure epoxy is about 3.35 GPa, and Young's modulus of the EMC may be higher than Young's modulus of pure epoxy by adding additives. Young's modulus of EMC may be greater than 3.5 GPa.

Portions of the EMC matrix 500M that overlies the horizontal plane including the top surfaces of the semiconductor dies (302, 304) may be removed by a planarization process. For example, the portions of the EMC matrix 500M that overlies the horizontal plane may be removed using a chemical mechanical planarization (CMP). The combination of the remaining portion of the EMC matrix 500M, the semiconductor dies (302, 304), the die-side underfill material portions 402, and the two-dimensional array of interposers 102 includes a reconstituted wafer 502W. Each portion of the EMC matrix 500M located within a unit area UA constitutes an EMC die frame.

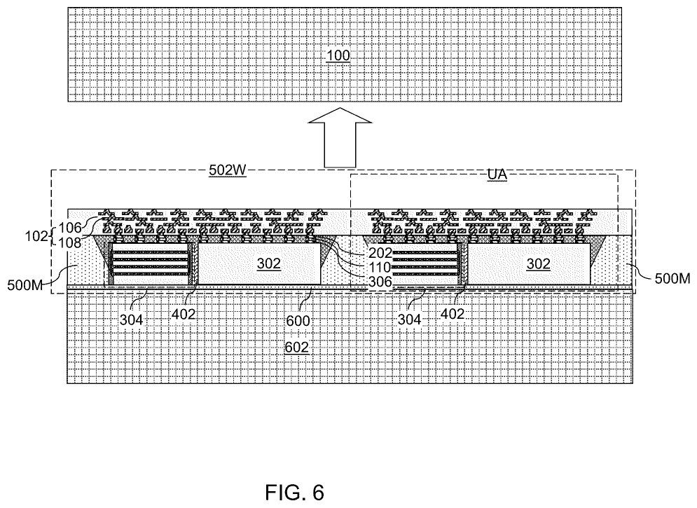

Referring to FIG. 6, a second adhesive layer 600 may be applied to the physically exposed planar surface of the reconstituted wafer 502W, i.e., the physically exposed surfaces of the EMC matrix 500M, the semiconductor dies (302, 304), and the die-side underfill material portions 402. In one embodiment, the second adhesive layer 600 may include a same material as, or may include a different material from, the material of the first adhesive layer 104. In embodiments in which the first adhesive layer 104 includes a thermally decomposing adhesive material, the second adhesive layer 600 may include another thermally decomposing adhesive material that decomposes at a higher temperature, or may include a light-to-heat conversion material.

A second carrier substrate 602 may be attached to the second adhesive layer 600. The second carrier substrate 602 may be attached to the opposite side of the reconstituted wafer 502W relative to the first carrier substrate 100. Generally, the second carrier substrate 602 may include any material that may be used for the first carrier substrate 100. The thickness of the second carrier substrate 602 may be in a range from 500 microns to 2,000 microns, although lesser and greater thicknesses may also be used.

The first adhesive layer 104 may be decomposed by ultraviolet radiation or by a thermal anneal at a debonding temperature. In embodiments in which the first carrier substrate 100 includes an optically transparent material and the first adhesive layer 104 includes an LTHC layer, the first adhesive layer 104 may be decomposed by irradiating ultraviolet light through the transparent carrier substrate. The LTHC layer may be absorb the ultraviolet radiation and generate heat, which decomposes the material of the LTHC layer and cause the transparent first carrier substrate 100 to be detached from the reconstituted wafer 502W. In embodiments in which the first adhesive layer 104 includes a thermally decomposing adhesive material, a thermal anneal process at a debonding temperature may be performed to detach the first carrier substrate 100 from the reconstituted wafer 502W.

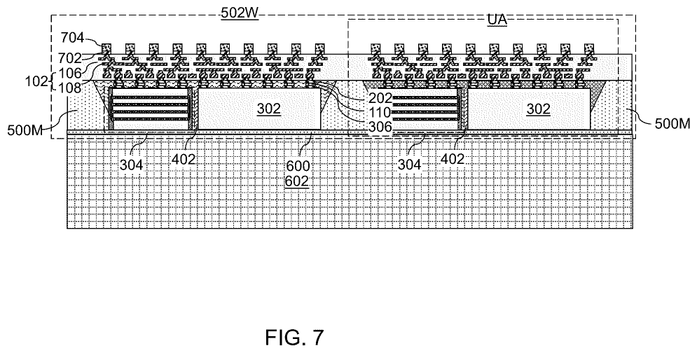

Referring to FIG. 7, interposer bonding pads 702 and second solder material portions 704 may be formed by depositing and patterning a stack of at least one metallic material that may function as metallic bumps and a solder material layer. The metallic fill material for the interposer bonding pads 702 may include copper. Other suitable materials are within the contemplated scope of disclosure. The thickness of the interposer bonding pads 702 may be in a range from 5 microns to 100 microns, although lesser or greater thicknesses may also be used. The interposer bonding pads 702 and the second solder material portions 704 may have horizontal cross-sectional shapes of rectangles, rounded rectangles, or circles. Other suitable shapes are within the contemplated scope of disclosure. In embodiments in which the interposer bonding pads 702 are formed as C4 (controlled collapse chip connection) pads, the thickness of the interposer bonding pads 702 may be in a range from 5 microns to 50 microns, although lesser or greater thicknesses may also be used. In some embodiments, the interposer bonding pads 702 may be, or include, underbump metallization (UBM) structures. The configurations of the interposer bonding pads 702 are not limited to be fan-out structures. Alternatively, the interposer bonding pads 702 may be configured for microbump bonding (i.e., C2 bonding), and may have a thickness in a range from 30 microns to 100 microns, although lesser or greater thicknesses may also be used. In such an embodiment, the interposer bonding pads 702 may be formed as an array of microbumps (such as copper pillars) having a lateral dimension in a range from 10 microns to 25 microns, and having a pitch in a range from 20 microns to 50 microns.

The interposer bonding pads 702 and the second solder material portions 704 may be formed on the opposite side of the EMC matrix 500M and the two-dimensional array of sets of semiconductor dies (302, 304) relative to the interposer layer. The interposer layer includes a three-dimensional array of interposers 102. Each interposer 102 may be located within a respective unit area UA. Each interposer 102 may include redistribution dielectric layers 106, redistribution wiring interconnects 108 embedded in the redistribution dielectric layers 106, and interposer bonding pads 702. The interposer bonding pads 702 may be located on an opposite side of the redistribution-side bonding structures 202 relative to the redistribution dielectric layers 106, and may be electrically connected to a respective one of the redistribution-side bonding structures 202.

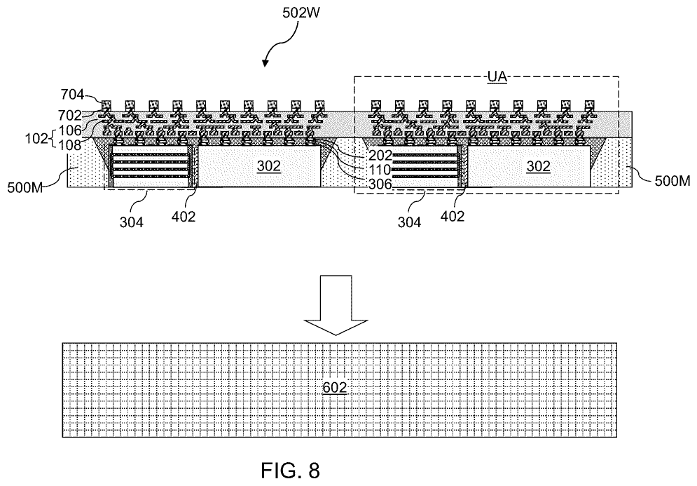

Referring to FIG. 8, the second adhesive layer 600 may be decomposed by ultraviolet radiation or by a thermal anneal at a debonding temperature. In embodiments in which the second carrier substrate 602 includes an optically transparent material and the second adhesive layer 600 includes an LTHC layer, the second adhesive layer 600 may be decomposed by irradiating ultraviolet light through the transparent carrier substrate. In embodiments in which the second adhesive layer 600 includes a thermally decomposing adhesive material, a thermal anneal process at a debonding temperature may be performed to detach the second carrier substrate 602 from the reconstituted wafer 502W.

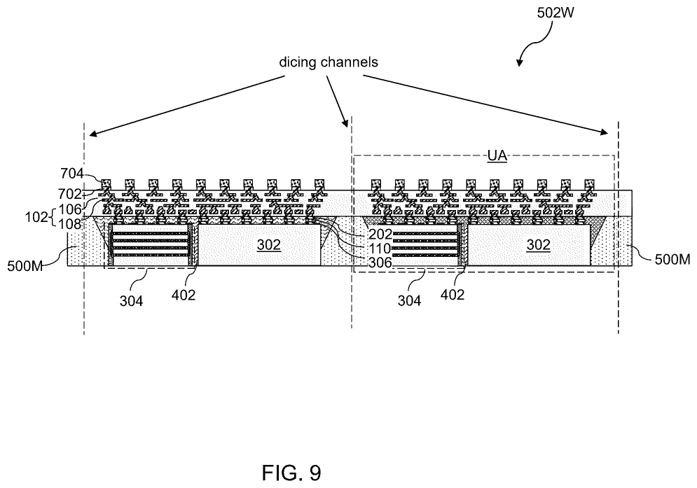

Referring to FIG. 9, the reconstituted wafer 502W including the interposer bonding pads 702 may be subsequently diced along dicing channels by performing a dicing process. The dicing channels correspond to the boundaries between neighboring pairs of die areas DA. Each diced unit from the reconstituted wafer 502W may include a fan-out package 500. In other words, each diced portion of the assembly of the two-dimensional array of sets of semiconductor dies (302, 304), the two-dimensional array of die-side underfill material portions 402, the EMC matrix 500M, and the two-dimensional array of interposers 102 constitutes a fan-out package 500. Each diced portion of the EMC matrix 500M constitutes a molding compound die frame 502. Each diced portion of the interposer layer (which includes the two-dimensional array of interposers 102) constitutes an interposer 102.

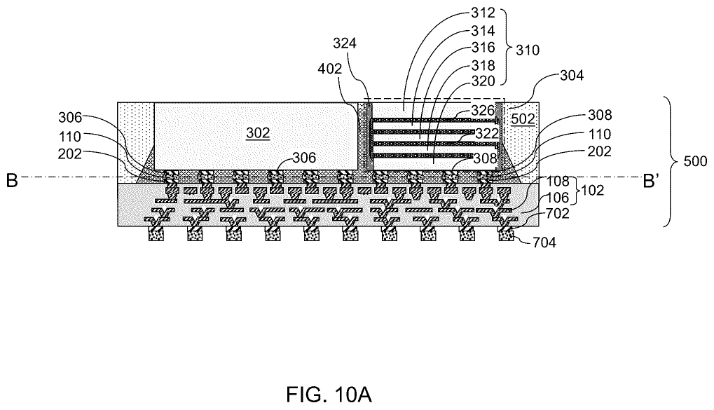

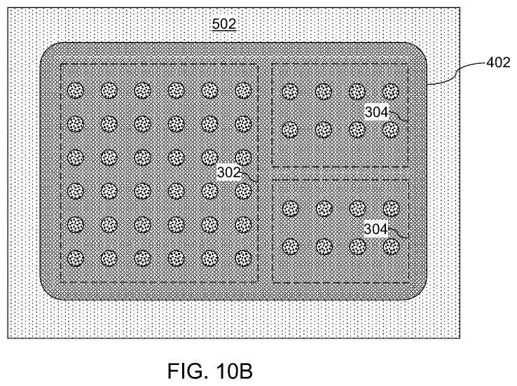

Referring to FIGS. 10A and 10B, a fan-out package 500 obtained by dicing the first exemplary structure at the processing steps of FIG. 10 is illustrated. The fan-out package 500 includes an interposer 102 including redistribution-side bonding structures 202, at least one semiconductor die (302, 304) including a respective set of die-side bonding structures (306, 308) that is attached to the redistribution-side bonding structures 202 through a respective set of first solder material portions 110, a die-side underfill material portion 402 laterally surrounding the redistribution-side bonding structures 202 and the die-side bonding structures (306, 308) of the at least one semiconductor die (302, 304).

The fan-out package 500 may include a molding compound die frame 502 laterally surrounding the at least one semiconductor die (302, 304) and including a molding compound material. In one embodiment, the molding compound die frame 502 may include sidewalls that are vertically coincident with sidewalls of the interposer 102, i.e., located within same vertical planes as the sidewalls of the interposer 102. Generally, the molding compound die frame 502 may be formed around the at least one semiconductor die (302, 304) after formation of the die-side underfill material portion 402 within each fan-out package 500. The molding compound material contacts a peripheral portion of a planar surface of the interposer 102.

Generally an assembly including at least one semiconductor die (302, 304) and an interposer 102 is provided. The assembly may be in a form of a package, i.e., a semiconductor package. In one embodiment, the assembly may include a fin-out package including at least one semiconductor die (302, 304), an interposer 102 attached to the at least one semiconductor die (302, 304), and a die-side underfill material portion 402 located between the at least one semiconductor die (302, 304) and the interposer 102.

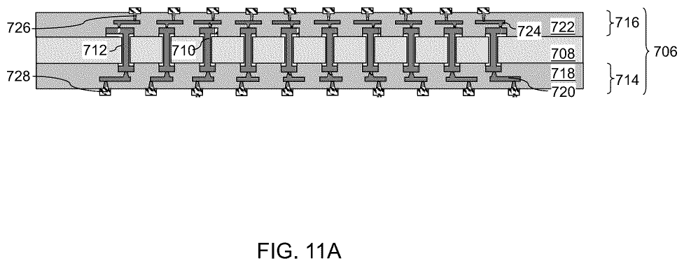

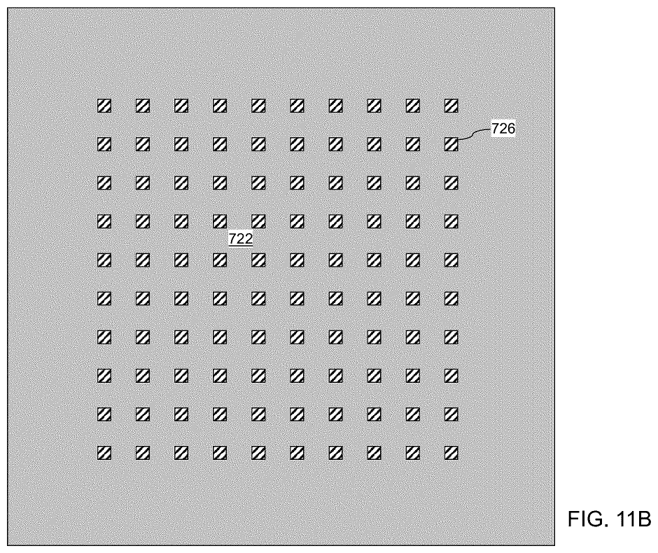

Referring to FIGS. 11A and 11B, a packaging substrate 706 is provided. The packaging substrate 706 may be a cored packaging substrate including a core substrate 708, or a coreless packaging substrate that does not include a package core. Alternatively, the packaging substrate 706 may include a system-on-integrated packaging substrate (SoIS) including redistribution layers and/or dielectric interlayers, at least one embedded interposer (such as a silicon interposer). Such a system-integrated packaging substrate may include layer-to-layer interconnections using solder material portions, microbumps, underfill material portions (such as molded underfill material portions), and/or an adhesion film. While this disclosure is described using an exemplary substrate package, it is understood that the scope of this disclosure is not limited by any particular type of substrate package and may include an SoIS. The core substrate 708 may include a glass epoxy plate including an array of through-plate holes. An array of through-core via structures 710 including a metallic material may be provided in the through-plate holes. Each through-core via structure 710 may, or may not, include a cylindrical hollow therein. Optionally, dielectric liners 712 may be used to electrically isolate the through-core via structures 710 from the core substrate 708.

The packaging substrate 706 may include board-side surface laminar circuit (SLC) 714 and a chip-side surface laminar circuit (SLC) 716. The board-side SLC may include board-side insulating layers 718 embedding board-side wiring interconnects 720. The chip-side SLC 716 may include chip-side insulating layers 722 embedding chip-side wiring interconnects 724. The board-side insulating layers 718 and the chip-side insulating layers 722 may include a photosensitive epoxy material that may be lithographically patterned and subsequently cured. The board-side wiring interconnects 720 and the chip-side wiring interconnects 724 may include copper that may be deposited by electroplating within patterns in the board-side insulating layers 718 or the chip-side insulating layers 722.

In one embodiment, the packaging substrate 706 includes a chip-side surface laminar circuit 716 including chip-side wiring interconnects 724 connected to an array of substrate bonding pads 726 that may be bonded to the array of second solder material portions 704, and a board-side surface laminar circuit 714 including board-side wiring interconnects 720 connected to an array of board-side bonding pads 728. The array of board-side bonding pads 728 is configured to allow bonding through solder balls. The array of substrate bonding pads 726 may be configured to allow bonding through C4 solder balls. Generally, any type of packaging substrate 706 may be used. While this disclosure is described using an embodiment in which the packaging substrate 706 includes a chip-side surface laminar circuit 716 and a board-side surface laminar circuit 714, embodiments are expressly contemplated herein in which one of the chip-side surface laminar circuit 716 and the board-side surface laminar circuit 714 is omitted, or is replaced with an array of bonding structures such as microbumps. In an illustrative example, the chip-side surface laminar circuit 716 may be replaced with an array of microbumps or any other array of bonding structures.

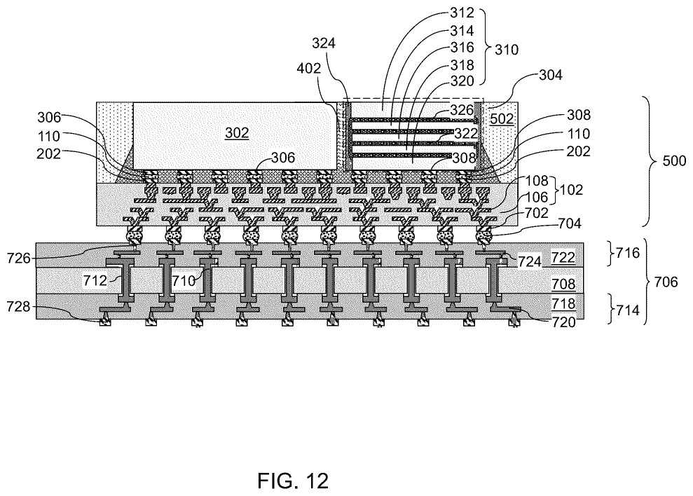

Referring to FIG. 12, the fan-out package 500 may be disposed over the packaging substrate 706 with an array of the second solder material portions 704 therebetween. In embodiments in which the second solder material portions 704 are formed on the interposer bonding pads 702 of the fan-out package 500, the second solder material portions 704 may be disposed on the substrate bonding pads 726 of the packaging substrate 706. A reflow process may be performed to reflow the second solder material portions 704, thereby inducing bonding between the fan-out package 500 and the packaging substrate 706. Each second solder material portion 704 may be bonded to a respective one of the interposer bonding pads 702 and to a respective one of the substrate bonding pads 726. In one embodiment, the second solder material portions 704 may include C4 solder balls, and the fan-out package 500 may be attached to the packaging substrate 706 through an array of C4 solder balls. Generally, the fan-out package 500 may be bonded to the packaging substrate 706 such that the interposer 102 is bonded to the packaging substrate 706 by an array of solder material portions (such as the second solder material portions 704).

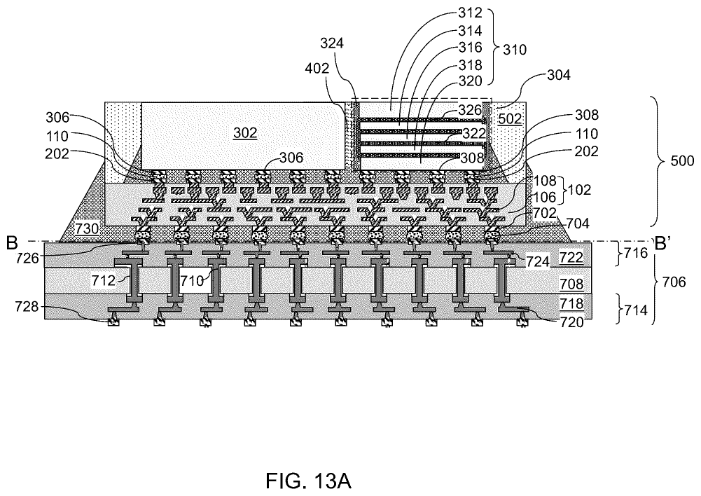

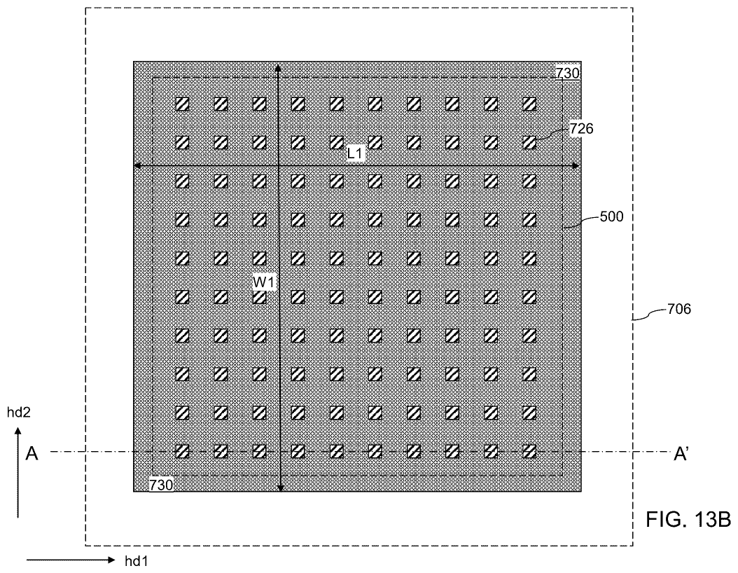

Referring to FIGS. 13A and 13B, an underfill material may be applied to the gap between the fan-out package 500 and the packaging substrate 706. The applied and deposited portions of the underfill material are herein referred to as package side underfill material portions 730. Generally, at least one package side underfill material portion 730 may be formed in the gap between the fan-out package 500 and the packaging substrate 706 and at corner regions of the interposer 102 and may contact a surface segment of a horizontal surface of the interposer 102. The surface segment may include a predominant portion of the horizontal surface of the interposer 102 that faces the packaging substrate 706. In one embodiment, the surface segment may include a center region of the horizontal surface of the interposer 102 that faces the packaging substrate 706, and may extend to center portions of four sides of a rectangular periphery of the horizontal surface. The fraction of the area of the surface segment relative to the total area of the horizontal surface of the interposer 102 that faces the packaging substrate 706 may be in a range from 50% to 99%, such as from 70% to 95%.

The underfill material may include a filler material or may be free of a filler material. Generally, the volume fraction of the filler material in the underfill material may be selected such that underfill material to adjust a Young's modulus of the underfill material. In one embodiment, the underfill material may include a filler material at a volume fraction in a range from 0.01% to 80% and a resin at a volume fraction in a range from 20% to 99.9%.

In one embodiment, the package side underfill material portion 730 may contact a respective set of at least one solder material portion within a subset of the second solder material portions 704. The subset of the solder material portions is herein referred to as a second subset of the second solder material portions 704. The second subset of the second solder material portions 704 may include four second solder material portions 704 located at the four corners of the array of second solder material portions 704, and may include additional second solder material portions 704 that are proximal to the four corners of the array of second solder material portions 704.

In one embodiment, the package side underfill material portion 730 may be formed directly on a respective horizontal surface segment of the packaging substrate 706 and directly on at least one corner segment of a horizontal surface of the interposer 102. The package side underfill material portion 730 may contact a subset of the interposer bonding pads 702 and a subset of the substrate bonding pads 726. In one embodiment, the package side underfill material portion 730 may have a first length L1 along a first horizontal direction hd1, and a first width W1 along a second horizontal direction hd2. In one embodiment, the first horizontal direction hd1 may be parallel to a side of the fan-out package 500, and the second horizontal direction hd2 may be parallel to another side of the fan-out package 500 as shown, for example, in FIG. 13B.

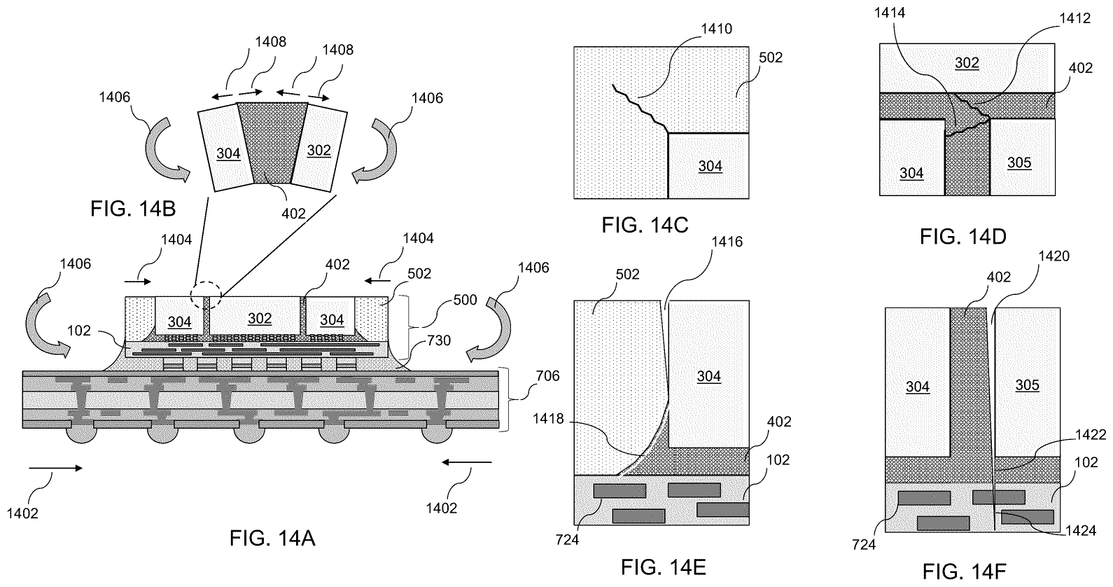

FIG. 14A is a vertical cross-sectional view of a further exemplary structure in which thermal stresses may cause mechanical degradation, and FIG. 14B is a vertical cross-sectional view of an enlarged portion of the exemplary structure of FIG. 14A illustrating thermally-induced deformations, according to various embodiments. FIGS. 14C and 14D are top views of respective portions of the exemplary structure of FIG. 14A in which thermally-induced cracking may occur, and FIGS. 14E and 14F are vertical cross-section views of respective portions of the exemplary structure of FIG. 14A in which thermally-induced delamination and cracking may occur, according to various embodiments. The exemplary structure of FIG. 14A may be similar to the exemplary structure of FIGS. 13A and 13B. In this regard, the exemplary structure may include a fan-out package 500, which includes an interposer 102 electrically coupled to one or more semiconductor dies (302, 304), and a packaging substrate 706 electrically coupled to the interposer 102. A die side underfill material portion 402 may be formed in contact with the interposer 102 and the one or more semiconductor dies (302, 304), and a package side underfill material portion 730 may be formed between the interposer 102 and the packaging substrate 706. A molding compound die frame 502 may be formed in contact with the one or more semiconductor dies (302, 304) and the interposer 102 and may provide mechanical support to the one or more semiconductor dies (302, 304) and the interposer 102.

Thermally-induced stresses/strains may develop during thermal cycling due to a mismatch between the thermal expansion coefficients of the various components of the exemplary structure of FIG. 14A. Such stresses/strains may lead to mechanical degradation such as cracking, delamination, etc. For example, the one or more semiconductor dies (302, 304) may have a thermal expansion coefficient that may be in a range from approximately 4 ppm to approximately 5 ppm while the packaging substrate 706 may have a thermal expansion coefficient that is in a range from approximately 12 ppm to approximately 19 ppm. Thus, upon cooling from a first temperature to a second temperature, the packaging substrate 706 may tend to mechanically contract (i.e., shrink) to a greater degree than a corresponding contraction of the fan-out package 500. As such, a first thermal contraction stress 1402 may develop in the packaging substrate 706, and a second thermal contraction stress 1404 may develop in the fan-out package 500. As indicated by the size of the arrows corresponding to the first thermal contraction stress 1402 relative to the size of the arrows corresponding to the second thermal contraction stress 1404, the first thermal contraction stress 1402 may be larger than the second thermal contraction stress 1404. Such a difference in stresses may generate bending moments 1406 that may cause deformation of the various components of the exemplary structure of FIG. 14A relative to one another as shown, for example, in FIG. 14B. Although in this example embodiment, thermal contraction stresses/strains are described, similar thermal expansion stresses/strains may also develop in response to temperature increases of the exemplary structure of FIG. 14A.

As mentioned above, FIG. 14B illustrates is a vertical cross-sectional view of an enlarged portion of the exemplary structure of FIG. 14A illustrating thermally-induced deformations. As shown, the bending moments 1406 may generate tensile stresses 1408 at interfaces between the first semiconductor die 302 and the die-side underfill material portion 402, and between the second semiconductor die 304 and the die-side underfill material portion 402. Additional stresses/strains may develop between various other interfaces, such as interfaces between the molding compound die frame 502 and the one or more semiconductor dies (302, 304), between the die-side underfill material portion 402 and the interposer 102, between the package side underfill material portions 730 and the interposer 102, between the package side underfill material portions 730 and the packaging substrate 706, etc. Such stresses may lead to cracking, delamination, and other mechanical degradation, as described in greater detail with reference to FIGS. 14C to 14F, below.

FIG. 14C is a top view of a portion of the fan-out package 500, of the exemplary structure of FIG. 14A, in which a first crack 1410 may be formed in the molding compound die frame 502, according to various embodiments. The first crack 1410 may be caused due to thermally-induced stresses/strains at interfaces between the molding compound die frame 502 and the second semiconductor die 304. For example, the second semiconductor die 304 may have a lower coefficient of thermal expansion than that of the molding compound die frame 502. Under a certain range of temperature variation (e.g., temperature reduction in this example) thermal stresses may develop that may exceed a threshold for crack formation. For example, sharp geometrical features, such as the corner of the second semiconductor die 304, may lead to a stress concentration at the corner. In this example, the stress concentration may have a maximum value at the corner of the second semiconductor die 304 such that the first crack 1410 may nucleate from the corner of the second semiconductor die 304. Once initiated, the first crack 1410 may propagate within the molding compound die frame 502, as shown in FIG. 14C.

FIG. 14D is a top view of another portion of the fan-out package 500, of the exemplary structure of FIG. 14A. As shown, the top view of FIG. 14D illustrates interfaces between the die-side underfill material portion 402 and the first semiconductor die 302, between the die-side underfill material portion 402 and a semiconductor die 304, and between the die-side underfill material portion 402 a third semiconductor die 305. In this example embodiment, a second crack 1412 and a third crack 1414 may develop in the die-side underfill material portion 402. As described above, one or both of the second crack 1412 and the third crack 1414 may nucleate from stresses concentrated at or near corners of the second semiconductor die 304 and the third semiconductor die 305. Alternatively, cracks may be initiated at flat interfaces and may propagate within the die-side underfill material portion 402. For example, the second crack 1412 may be initiated at the interface between the first semiconductor die 302 and the die-side underfill material portion 402 and may propagate within the die-side underfill material portion 402 toward the third semiconductor die 305. Various other thermally-induced deformations may occur, such as delamination and cracks that propagate into other components, as described in greater detail with reference to FIGS. 14E and 14F, below.

As mentioned above, FIGS. 14E and 14F are vertical cross-section views of respective portions of the exemplary structure of FIG. 14A in which thermally-induced delamination and cracking may occur, according to various embodiments. The view of FIG. 14E shows interfaces between the molding compound die frame 502 and the second semiconductor die 304, between the molding compound die frame 502 and the die-side underfill material portion 402, between the die-side underfill material portion 402 and the second semiconductor die 304, and between the die-side underfill material portion 402 and the interposer 102. Cracks and/or delamination may occur at one or more of these interfaces. For example, a first delamination 1416 may occur at the interface between the molding compound die frame 502 and the second semiconductor die 304, as shown. Similarly, a second delamination 1418 may occur between the die-side underfill material portion 402 and the molding compound die frame 502. Other mechanical degradations may involve two or more components as shown, for example, in FIG. 14F as described in greater detail, below.

FIG. 14F is a vertical cross-sectional view of a further portion of the exemplary structure of FIG. 14A showing thermally induced delamination and cracking, according to various embodiments. The view of FIG. 14F shows interfaces between the die-side underfill material portion 402 and the second semiconductor die 304, between the die-side underfill material portion 402 and the third semiconductor die 305, and between die-side underfill material portion 402, and the interposer 102. As shown, a third delamination 1420 may form between the die-side underfill material portion 402 and the third semiconductor die 305. As such, the die-side underfill material portion 402 may become de-bonded (i.e., delaminated) from a surface of the third semiconductor die 305.

The delamination (i.e., the third delamination 1420) of the portion of the die-side underfill material portion 402 from the third semiconductor die 305 may relieve a thermal stress that previously existed at the interface between the die-side underfill material portion 402 and the third semiconductor die 305. However, such a delamination may give rise to a displacement of a surface of the die-side underfill material portion 402 relative to a surface of the third semiconductor die 305. Such a displacement may cause further stress in a remaining constrained portion of the die-side underfill material portion 402, which may thereby nucleate a fourth crack 1422 in the die-side underfill material portion 402. The displacement of respective surfaces of the fourth crack 1422 may generate additional stresses at the interface between the die-side underfill material portion 402 and the interposer 102. Such additional stresses may generate a fifth crack 1424 that may propagate within the interposer 102. Such a propagating fifth crack 1424 may further propagate through one or more chip-side wiring interconnects 724 thereby causing damage to such interconnects.

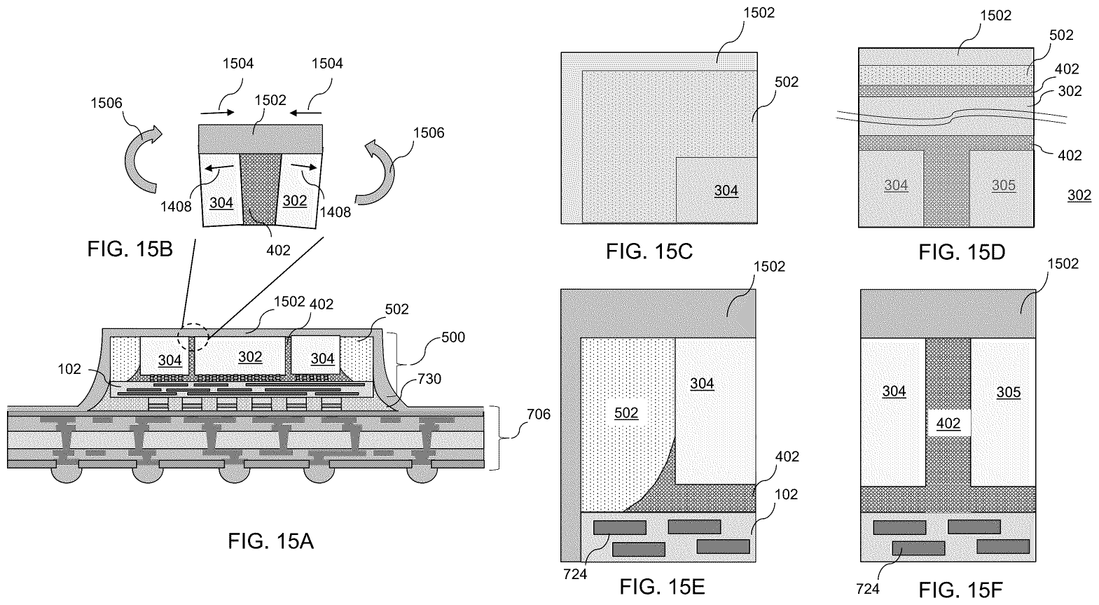

FIG. 15A is a vertical cross-sectional view of a further exemplary structure including a capping layer 1502 that may mitigate thermally-induced mechanical degradation, and FIG. 15B is a vertical cross-sectional view of an enlarged portion of the exemplary structure of FIG. 15A illustrating a portion of the capping layer 1502, according to various embodiments. FIG. 15C is a top view of a portion of the exemplary structure of FIG. 15A showing a portion of the capping layer 1502, and FIG. 15D is a top view of a further portion of the exemplary structure of FIG. 15A showing a respective further portion of the capping layer 1502, according to various embodiments. FIG. 15E is a vertical cross-sectional view of a portion of the exemplary structure of FIG. 15A showing a side view of a portion of the capping layer 1502, and FIG. 15F is a vertical cross-sectional view of a further portion of the exemplary structure of FIG. 15A showing a side view of a respective further portion of the capping layer 1502, according to various embodiments.

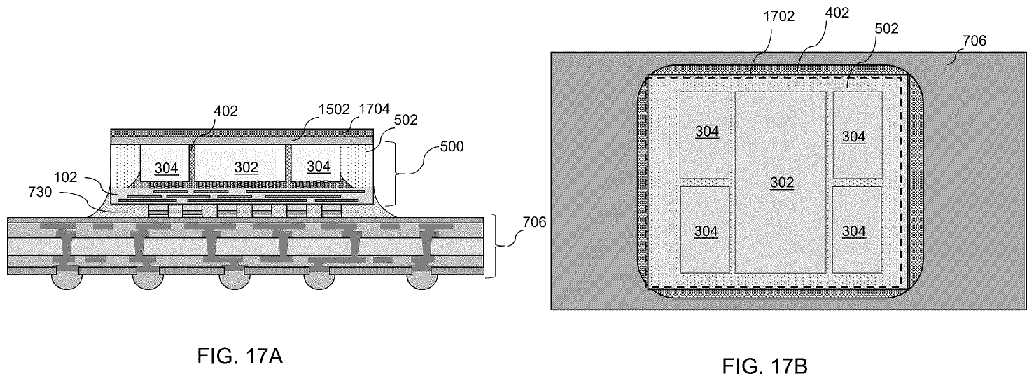

As shown in FIG. 15A, the capping layer 1502 may be formed as a continuous structure covering respective surfaces of the first semiconductor die 302, the second semiconductor dies 304, the molding compound die frame 502, the die-side underfill material portion 402, and the packaging substrate 706. In other embodiments, the capping layer 1502 may cover fewer components of the exemplary structure, as described in greater detail with reference to FIGS. 17A to 18B, 20A, and 20B, below. The capping layer 1502 may be chosen to have a thermal expansion coefficient that is different from the thermal expansion coefficients of the various other components of the intermediate structure of FIG. 15A. For example, the capping layer 1502 may be chosen to have a thermal expansion coefficient that is in a range from approximately 9 ppm to approximately 30 ppm. Other ranges of the thermal expansion coefficient are within the contemplated scope of this disclosure in other embodiments. In various example embodiments, the capping layer may include one or more of stainless steel (9.9 ppm to 17.3 ppm), copper (16.7 ppm), nickel (12.8 ppm), tungsten (4.5 ppm), aluminum (25.5 ppm), magnalium (23.8 ppm), titanium (8.5 ppm to 9 ppm), silver (18.8 ppm), and gold (13.9 ppm). Various other materials may be used for the capping layer 1502 in other embodiments, and are may be considered within the contemplated scope of this disclosure.

The capping layer 1502 may act to mitigate damage to the exemplary structure of FIG. 15A due to thermally-induced stresses/strains. For example, the capping layer 1502 may be chosen to have a thermal expansion coefficient that is larger than that of the fan-out package 500. Upon cooling from a first temperature to a second temperature, the capping layer 1502 may tend to contract to a greater extent than the fan-out package 500. This contraction of the capping layer 1502 may thereby generate compressive stresses 1504 (e.g., see FIG. 15B) that may counteract the tensile stresses 1408 at the interfaces between the die-side underfill material portion 402 and the first semiconductor die 302 and between the die-side underfill material portion 402 and the second semiconductor die 304. As such, the capping layer 1502 may generate a bending moment 1506 that may counteract the bending moment 1406 generated by the difference in thermal expansion coefficient of the fan-out package 500 relative to the that of the packaging substrate 706. In this way, thermally-induced cracking, delamination, and other mechanical degradations may be reduced or eliminated.

The portion of the exemplary structure of FIG. 15A covered by the capping layer 1502 in FIG. 15C corresponds to the portion of the exemplary structure of FIG. 14A shown in FIG. 14C. As such, the capping layer 1502 covers a portion of the second semiconductor die 304 and a portion of the molding compound die frame 502. In this example embodiment, the presence of the capping layer 1502 may prevent the formation of the first crack 1410 shown in FIG. 14C. The portion of the exemplary structure of FIG. 15A covered by the capping layer 1502 in FIG. 15D corresponds to the portion of the exemplary structure of FIG. 14A shown in FIG. 14D. As such, the capping layer 1502 may cover a portion of the first semiconductor die 302, a portion of the molding compound die frame 502, a portion of the die-side underfill material portion 402, a portion of the second semiconductor die 304, and a portion of the third semiconductor die 305. In this example embodiment, the presence of the capping layer 1502 may prevent the formation of the second crack 1412 and the third crack 1414 shown in FIG. 14C.

The portion of the exemplary structure of FIG. 15A covered by the capping layer 1502 in FIG. 15E corresponds to the portion of the exemplary structure of FIG. 14A shown in FIG. 14E. As such, the capping layer 1502 includes a top portion that covers a top surface of the second semiconductor die 304, a top surface of the molding compound die frame 502 and a top surface of the side underfill material portion 402. The capping layer 1502 further includes a side portion covering a side surface of the molding compound die frame 502 and a side surface of the interposer 102. The presence of the capping layer 1502 may act to prevent formation of the first delamination 1416 and the second delamination 1418 shown in FIG. 14E.

The portion of the exemplary structure of FIG. 15A covered by the capping layer 1502 in FIG. 15F corresponds to the portion of the exemplary structure of FIG. 14F shown in FIG. 14F. As such, the capping layer 1502 includes a top portion that covers a further top surface of the first semiconductor die 304, a further top surface of the molding compound die frame 502, a top surface of the die side underfill material portion 402, and a further top surface of the third semiconductor die 305. As such, the presence of the capping layer 1502 may prevent displacement of the die side underfill material portion 402 and molding compound die frame 502 relative to a surface of the third semiconductor die 305. The presence of the capping layer 1502 may thus prevent the third delamination 1420 as shown in FIG. 14F. Similarly, by preventing the third delamination 1420, the stress/strain within the molding compound die frame 502 and die-side underfill material portion 402 that might cause the fourth crack 1422 may be reduced, thereby preventing the formation of the fourth crack 1422 shown in FIG. 14F. In turn, the fifth crack 1424 may be prevented, thus reducing or eliminating damage to the chip-side wiring interconnects 724.

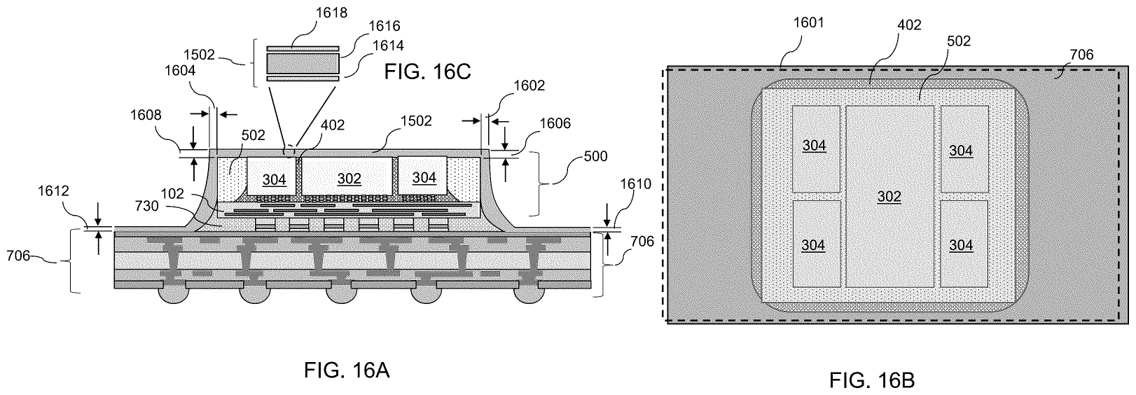

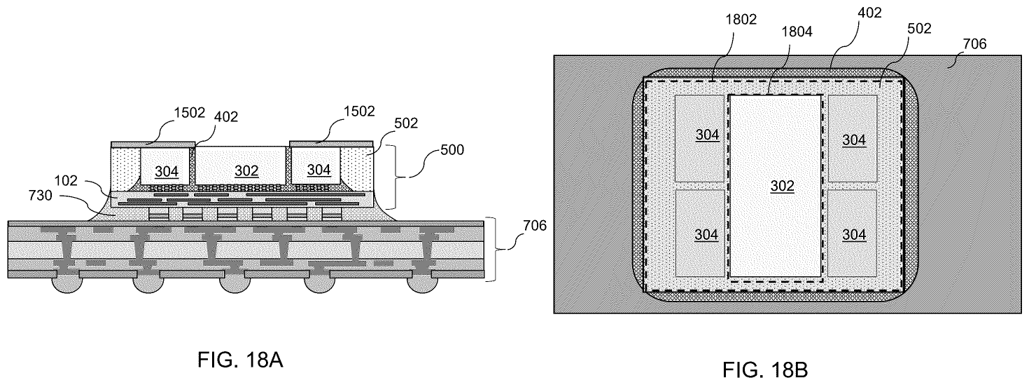

FIG. 16A is a vertical cross-sectional view of the exemplary structure of FIG. 15A showing further details of the capping layer 1502, and FIG. 16B is top view of the exemplary structure of FIGS. 15A and 16A, according to various embodiments. FIG. 16C is a vertical cross-sectional view of an enlarged portion of the capping layer 1502, according to various embodiments. As shown in FIG. 16B, the exemplary structure may include a plurality of semiconductor dies. In this example embodiment, the exemplary structure may include a single first semiconductor die 302 and four second semiconductor dies 304. Various other numbers and types of semiconductor dies may be included in other embodiments within the contemplated scope of this disclosure. As shown in both FIGS. 16A and 16B, the capping layer 1502 may be a continuous structure covering a region 1601 (e.g., see FIG. 16B) including respective surfaces of the first semiconductor die 302, the four second semiconductor dies 304, the die-side underfill material portion 402, the die side underfill material portion 402, and the packaging substrate 706. In other embodiments, the capping layer 1502 may be configured to cover fewer components, as described in greater detail with reference to FIGS. 17A to 18B, below.

As shown in FIG. 16A, the capping layer 1502 may have a first sidewall having a first thickness 1602 and a second sidewall having a second thickness 1604. The first sidewall may cover a first side of the molding compound die frame 502, a first sidewall of the interposer 102, and a first side of the package side underfill material portions 730. The second sidewall may cover a second side of the molding compound die frame 502, a second sidewall of the interposer 102, and a second side of the package side underfill material portions 730. Each of the first thickness 1602 and the second thickness 1604 may have a value in a range from approximately 0.001 mm to approximately 10 mm. In some embodiments, the first thickness 1602 and the second thickness 1604 may be equal, and in other embodiments the first thickness 1602 and the second thickness 1604 may have different values.

A top portion of the capping layer 1502 may have a uniform thickness or may have a thickness that varies with a position over the top portion of the capping layer. In this regard, the top portion of the capping layer 1502 may have a third thickness 1606 at one side of the exemplary structure and a fourth thickness 1608 at another side of the exemplary structure. In this embodiment, the third thickness 1606 and the fourth thickness 1608 may each have a value in a range from approximately 0.001 mm to approximately 10 mm. In some embodiments, the third thickness 1606 and the fourth thickness 1608 may be equal, and in other embodiments the third thickness 1606 and the fourth thickness 1608 may have different values.

As mentioned above, the thickness of the capping layer 1502 may vary with position over the surface of the capping layer 1502. For example, the portion of the capping layer 1502 that covers a top surface of the packaging substrate 706 may have a different thickness (or thicknesses) from that of other portions of the capping layer 1502 such as the top portion and the sidewall portions of the capping layer. For example, the capping layer 1502 may have a fifth thickness 1610 over a first side of the packaging substrate 706 and a sixth thickness 1612 over a second side of the packaging substrate 706. In this embodiment, the fifth thickness 1610 and the sixth thickness 1612 may each have a value in a range from approximately 0.001 mm to approximately 10 mm. In some embodiments, the fifth thickness 1610 and the sixth thickness 1612 may be equal, and in other embodiments the fifth thickness 1610 and the sixth thickness 1612 may be different.

FIG. 16C is a vertical cross-sectional enlarged view of a portion of the capping layer 1502, according to various embodiments. As shown, the capping layer 1502 may be formed as a multi-layer structure. In this example embodiment, the capping layer 1502 may be a tri-layer structure that includes a seed layer 1614, a bulk layer 1616, and a finish layer 1618. The seed layer 1614 may include one or more materials that may be deposited by a sputtering process, such as stainless steel, TiCu, TiW, TiN, and TaN. In other embodiments, the seed layer may include other materials that may be deposited using other deposition processes such as atomic layer deposition (ALD), chemical vapor deposition (CVD), metal-organic chemical vapor deposition (MOCVD), etc.

The bulk layer 1616 may include a material that may be deposited using an electro-plating process. For example, the bulk layer 1616 may include one or more of stainless steel, copper, nickel, tungsten, aluminum, magnalium, titanium, silver, and gold. The finish layer 1618 may be similar to the seed layer and may be deposited by a sputtering process. In this regard, the finish layer 1618 may include a material such as stainless steel, TiCu, TiW, TiN, and TaN. In certain embodiments, the seed layer 1614 and the finish layer 1618 may each have a thickness that is in a range from approximately 0.1 microns to approximately 0.3 microns, and the bulk layer 1616 may have a thickness in a range from approximately 0.5 microns to approximately 2,000 microns. Although this example embodiment includes a capping layer 1502 having a tri-layer structure, other embodiments may include capping layers with other structures. For example, the capping layer 1502 may include only the seed layer 1614 and the bulk layer 1616 or the capping layer 1502 may include only the bulk layer 1616. Other embodiments may include various other configurations of the capping layer 1502 including greater or fewer layers.

FIG. 17A is a vertical cross-sectional view of a further exemplary structure having a capping layer 1502 only over a fan-out package 500, and FIG. 17B is a top view of the exemplary structure of FIG. 17A, according to various embodiments. In this example embodiment, the fan-out package 500 may be similar to fan-out packages 500 of the embodiments of FIGS. 14A to 16B. In this regard, the fan-out package 500 may include a first semiconductor die 302, four second semiconductor dies 304 (e.g., see FIG. 17B), an interposer 102, a die-side underfill material portion 402, a molding compound die frame 502, and package side underfill material portion 730.

Unlike the exemplary structure of FIG. 16A, however, the capping layer 1502 may extend only over a top surface of the fan-out package 500. In this regard, the capping layer 1502 may extend over an area 1702 (e.g., see FIG. 17B) that covers respective top surfaces of the first semiconductor die 302, the four second semiconductor dies 304, top surfaces of the molding compound die frame 502, and top surfaces of the die-side underfill material portion 402. Unlike the embodiment of FIG. 16A, the capping layer 1502 in the exemplary structure of FIG. 17A does not cover side surfaces of the molding compound die frame 502, side surfaces of the package side underfill material portions 730, side surfaces of the interposer 102, and top surfaces of the packaging substrate 706. The capping layer 1502 in the exemplary structure of FIG. 17A may provide advantages in configurations in which cracking/delamination issues tend to only occur in the fan-out package 500. In some embodiments, a thermal interface material layer 1704 may be formed over the capping layer 1502. The presence of the thermal interface material 1704 may be used in embodiments having a package lid (not shown) formed over the exemplary structure of FIG. 17A.

Other configurations of the capping layer 1502, such as those described above with reference to FIGS. 15A to 16B, may be advantageous in other embodiments, where cracking may also occur in other components such as the interposer 102, in the package side underfill material portions 730, and/or in the packaging substrate 706. Thus, the configuration of the capping layer 1502 may be adapted to the particular configuration of a given exemplary structure and its tendency for thermally-induced mechanical degradation. Various other embodiments include respective other configurations of the capping layer 1502, as described in greater detail with reference to FIGS. 18A to 20B, below.

FIG. 18A is a vertical cross-sectional view of an exemplary structure having a capping layer 1502 only over a portion of a fan-out package 500, and FIG. 18B is a top view of the exemplary structure of FIG. 18A, according to various embodiments. In this example embodiment, the fan-out package 500 may be similar to fan-out packages 500 of the embodiments of FIGS. 14A to 17A. In this regard, the fan-out package 500 may include a first semiconductor die 302, four second semiconductor dies 304 (e.g., see FIG. 18B), an interposer 102, a die-side underfill material portion 402, a molding compound die frame 502, and package side underfill material portion 730.

Unlike the exemplary structure of FIGS. 17A and 17B, however, the capping layer 1502 may extend only over a portion of the top surface of the fan-out package 500. In this regard, the capping layer 1502 may extend over a region within a first boundary 1802 and external to a second boundary 1804 as shown, for example, in FIG. 18B. As such, the capping layer 1502 in this example embodiment covers respective top surfaces of the four second semiconductor dies 304, top surfaces of the molding compound die frame 502, and top surfaces of the die-side underfill material portion 402, but does not cover a top surface of the first semiconductor die 302. Such a configuration of the capping layer 1502 may be advantageous in embodiments in which the first semiconductor die 302 may have electrical connections on a top surface of the first semiconductor die 302. As such, in configurations in which the capping layer 1502 includes a conductive material, electrical short circuit connections between the first semiconductor die 302 and the capping layer 1502 may be avoided.

The capping layer 1502 of the exemplary structure of FIGS. 18A and 18B is similar to the capping layer 1502 of the exemplary structure of FIG. 17A in that the capping layer 1502 does not cover side surfaces of the molding compound die frame 502, side surfaces of the package side underfill material portions 730, side surfaces of the interposer 102, and top surfaces of the packaging substrate 706. As with the exemplary structure of FIG. 17A, the capping layer 1502 in the exemplary structure of FIG. 18A may provide advantages in configurations in which cracking/delamination issues tends to only occur in the fan-out package 500. In various embodiments, the capping layer 1502 may cover a portion of an area of one or more of the first semiconductor die 302, the second semiconductor dies 304, and the packaging substrate 706. For example, the capping layer 1502 may be formed over a portion of the area of the one or more of the first semiconductor die 302, the second semiconductor die 304, and the packaging substrate 706 that is in a range from approximately 0.1% to approximately 100% of the area of the one or more of the first semiconductor die 302, the second semiconductor die 304, and the packaging substrate 706.

In further embodiments, the capping layer 1502 may be configured to cover all of the semiconductor dies (302, 304) but may have a different thickness over different semiconductor dies. As described above with reference to FIG. 16A, the thickness of the capping may vary as a function of position. As such, it may be advantageous in certain embodiments to configure the capping layer 1502 to be thicker (not shown) over one or more of the semiconductor dies (302, 304). For example, in certain embodiments, the first semiconductor die may be a SoC die and the second semiconductor dies 304 may be HBM dies. As such, the first semiconductor die 302 may generate more heat than may be generated by the second semiconductor dies 304. Further, a material used to form the capping layer 1502 may have a thermal conductivity that varies with thickness.

For materials having a thermal conductivity that increases with thickness, it may be advantageous to form the capping layer 1502 to have a greater thickness over the first semiconductor die 302. The greater thickness of the capping layer 1502 may thereby provide an increased thermal conductivity that may allow for better removal of heat generated by the first semiconductor die 302. In other embodiments, it may be advantageous to have a reduced thickness over one or more semiconductor dies. For example, a reduced thickness of the capping layer 1502 over one or more dies may allow a greater volume of a thermal interface material (not shown) to be provided over one or more semiconductor dies to thereby increase removal of heat over the one or more semiconductor dies.

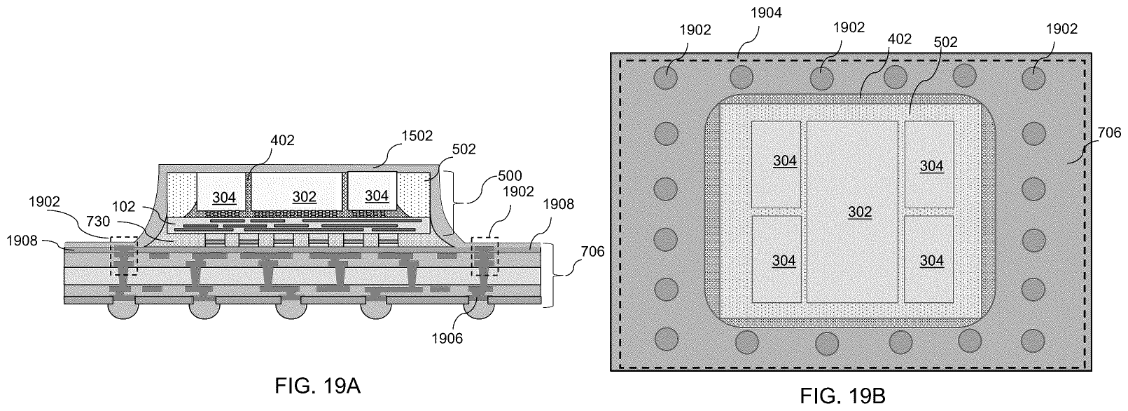

FIG. 19A is a vertical cross-sectional view of a further exemplary structure having a capping layer 1502 only and a pinning structure 1902, and FIG. 19B is a top view of the exemplary structure of FIG. 19A, according to various embodiments. As shown in FIG. 19B, the exemplary structure may be similar to the exemplary structures of FIGS. 15A to 16B. In this regard, the exemplary structure may include a single first semiconductor die 302 and four second semiconductor dies 304. Various other numbers and types of semiconductor dies may be included in other embodiments within the contemplated scope of this disclosure. As shown in both FIGS. 19A and 19B, the capping layer 1502 may be a continuous structure covering a region 1904 including respective top surfaces of the first semiconductor die 302, the four second semiconductor dies 304, the molding compound die frame 502, the die side underfill material portion 402, and the packaging substrate 706.

The exemplary structure of FIGS. 19A and 19B may be advantageous for embodiments that may otherwise be prone to cracking, delamination, and other mechanical degradation of the fan-out package 500 and the packaging substrate 706. As such, the capping layer 1502 may provide mechanical stability to various components of the fan-out package 500 as well as to the packaging substrate 706, as described above with reference to FIGS. 15C to 15F. The presence of the pinning structure 1902 may further strengthen the packaging substrate 706 and may reduce or eliminate mechanical deformations such as warping and/or reduce or eliminate other thermally-induced mechanical degradation, such as cracking, delamination, etc., as described above.

The pinning structures 1902 may be formed as one or more plated through holes that may be formed during processes used to form the packaging substrate 706. In this regard, the package substrate may include a dielectric layer 1908 formed on a top surface of the package substrate 706 and the pinning structures 1902 may formed as plated through holes protruding from the dielectric layer 1908. As shown in FIG. 19A, for example, the pinning structure 1902 may be formed as a structure that penetrates through an entire thickness of the packaging substrate 706 and may be connected to a non-conducting bonding pad 1906. In this way, the pinning structure 1902 may be bonded to another component, such as a PCB to provide added mechanical stability to the packaging substrate 706. Also, as shown in FIG. 19A, the capping layer 1502 may be configured such that a top surface of the pinning structure is covered by a portion of the capping layer 1502. As shown in FIG. 19B, the pinning structure may include a plurality of plated through holes located around a perimeter of the packaging substrate 706. In this example embodiment, the pinning structure 1902 includes six plated through holes located along top and bottom edges of the packaging substrate 706, and four additional plated through holes located along left and right side edges of the packaging substrate 706.

The pinning structure 1902 may include various other numbers of plated through holes in respective other embodiments. For example, in some embodiments, the pinning structure 1902 may include four plated through holes (not shown) located at respective four corners of the packaging substrate 706. Other embodiments may include an additional four plated through holes (not shown) located at the centers of respective edges of the packaging substrate 706 for a total of eight plated through holes making up the pinning structure 1902. Various other embodiments may include greater or fewer plated through holes in the contemplated scope of this disclosure.

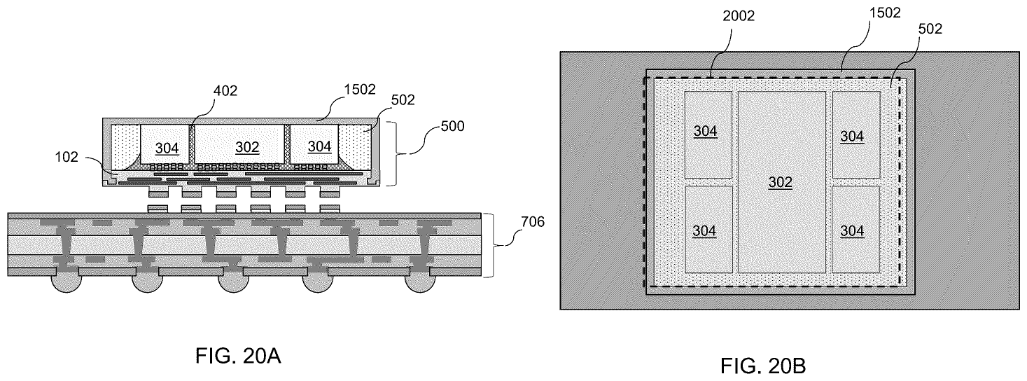

FIG. 20A is a vertical cross-sectional view of a further exemplary structure having a capping layer 1502 only on the fan-out package 500, and FIG. 20B is a top view of the exemplary structure of FIG. 19A, according to various embodiments. As shown, the fan-out package 500 may be formed as a separate, stand-alone structure that includes the capping layer 1502. As shown in FIG. 20A, the fan-out package 500 that includes the capping layer 1502 may be positioned relative to the packaging substrate 706 may be attached the packaging substrate 706 as described in greater detail above (e.g., see FIG. 12 and related description, above).

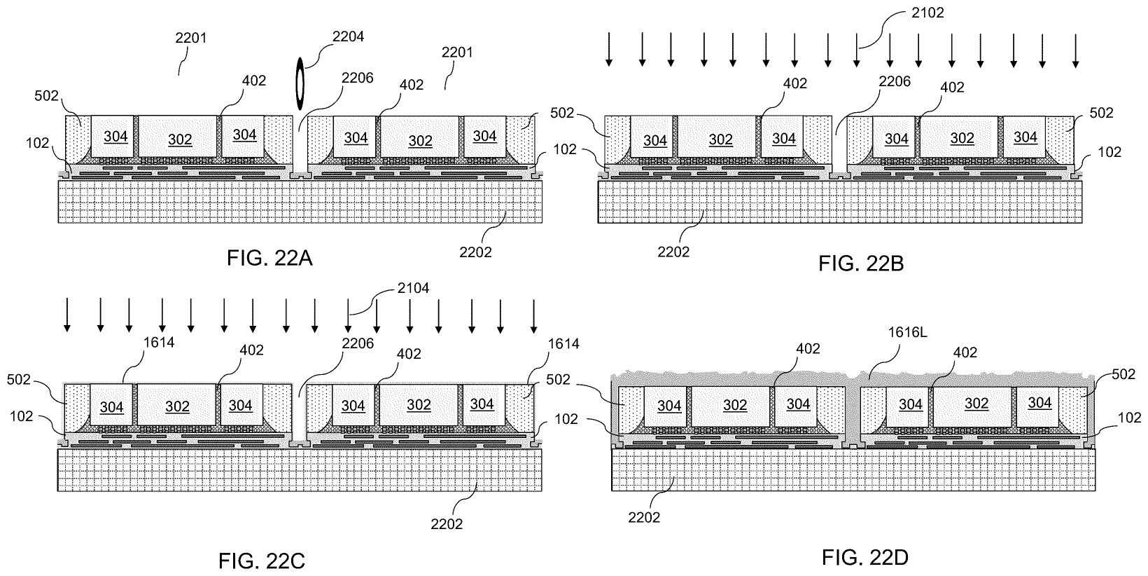

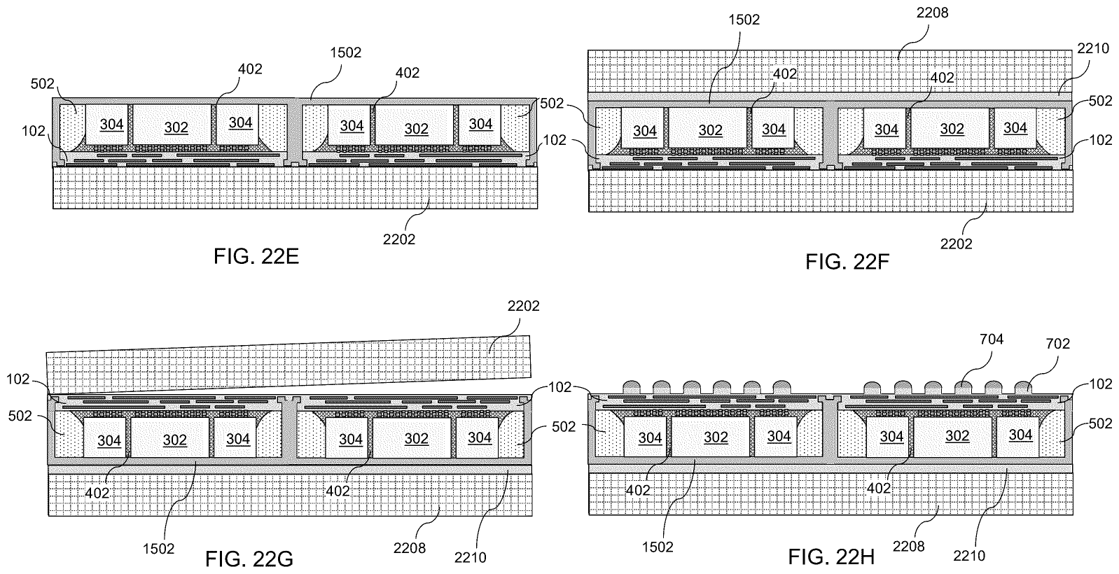

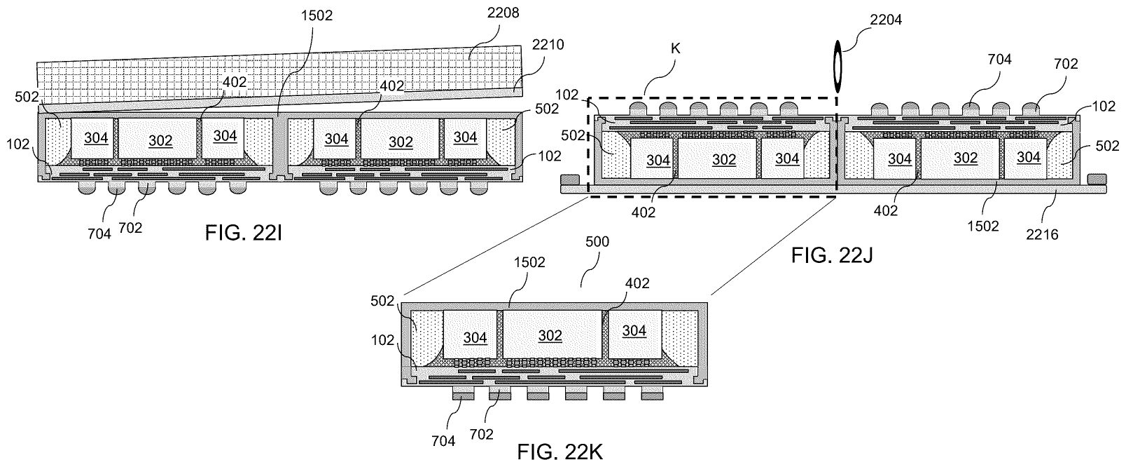

The process of forming such a fan-out package 500 including the capping layer 1502 is described in greater detail with reference to FIGS. 22A to 22K, below. The fan-out package 500 of FIG. 20A is similar to fan-out packages 500 of other embodiments described above with reference to FIGS. 14A to 19B. In this regard, the fan-out package 500 of FIG. 20A may include a plurality of semiconductor dies. In this example embodiment, the exemplary structure may include a single first semiconductor die 302 and four second semiconductor dies 304. Various other numbers and types of semiconductor dies may be included in other embodiments within the contemplated scope of this disclosure. The capping layer 1502 may be a continuous structure covering a region 2002 including respective top surfaces of the first semiconductor die 302, the four second semiconductor dies 304, the molding compound die frame 502, and the die side underfill material portion 402. The capping layer 1502 may also further cover side surfaces of the molding compound die frame 502 and the interposer 102 as shown, for example, in FIG. 20A.

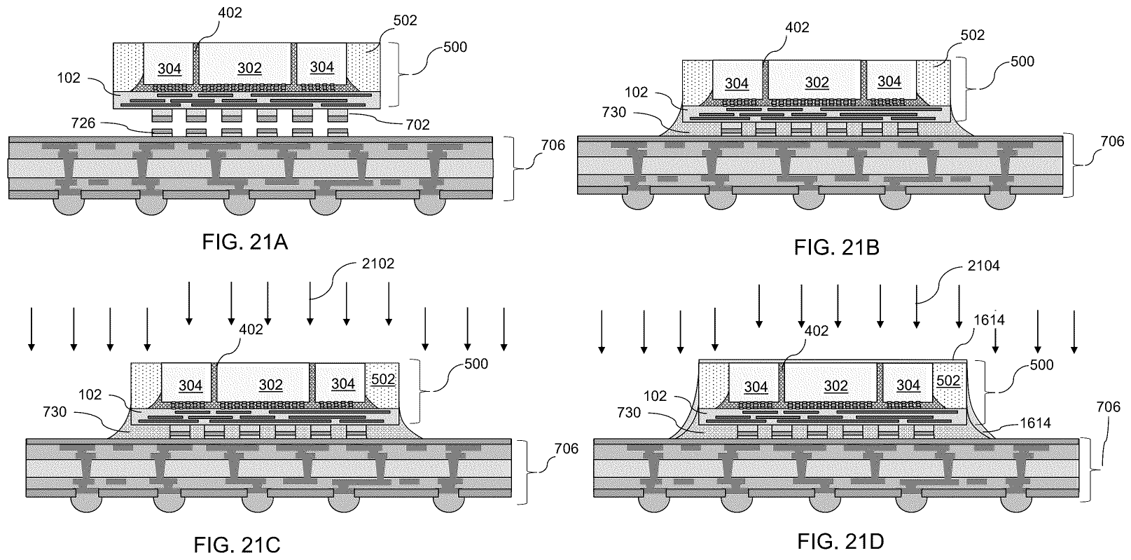

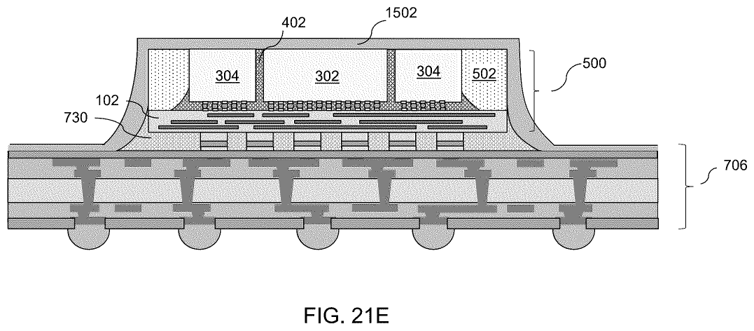

FIGS. 21A to 21D are vertical cross-sectional views of respective intermediate structures that may be used in the formation of a semiconductor structure having a capping layer 1502, and FIG. 21E is a vertical cross-sectional view of the semiconductor structure having the capping layer 1502. In this regard, FIG. 21A shows a fan-out package 500 positioned relative to a packaging substrate 706 prior to attachment of the fan-out package 500 to the packaging substrate 706. The fan-out package 500 may be formed using processes described in greater detail above with reference to FIGS. 1A to 10B. In this regard, the fan-out package 500 may include a first semiconductor die 302 and two or more second semiconductor dies 304 attached to, and electrically coupled to, an interposer 102. The fan-out package 500 may further include a die side underfill material portion 402 and a molding compound die frame 502. The interposer 102 may further include interposer bonding pads 702 that are configured to be bonded to corresponding substrate bonding pads 726. The packaging substrate 706 may be formed using processes described in greater detail above with reference to FIGS. 11A and 11B.

FIG. 21B is vertical cross-sectional view of a further intermediate structure that may be used in the formation of a semiconductor structure having a capping layer 1502, according to various embodiments. The intermediate structure of FIG. 21B may be formed from the intermediate structure of FIG. 21A by attaching the fan-out package 500 to the packaging substrate 706 and by forming a package side underfill material portion 730, as described in greater detail above with reference to FIGS. 13A and 13B.

FIG. 21C is vertical cross-sectional view of a further intermediate structure that may be used in the formation of a semiconductor structure having a capping layer 1502, according to various embodiments. The intermediate structure of FIG. 21C may be formed from the intermediate structure of FIG. 21B by performing a surface roughening process to increase roughness of the various surfaces of the intermediate structure of FIG. 21B. One or more etching processes may be performed to roughen the intermediate structure of FIG. 21B. In this regard, a wet or dry etch may be performed. For example, a physical etch may be performed by bombarding the intermediate structure with ions, as indicated schematically by the downward arrows 2102 in FIG. 21C. A physical etch may be performed, for example, by bombarding the surface with argon ions from an argon plasma source. Various other dry etch processes may be performed in other embodiments using other ions and process conditions.

In further embodiments, a wet (i.e., chemical) etch process may be performed to roughen the various surfaces of the intermediate structure of FIG. 21B. For example, a wet etch process may be performed by applying a mixture of acetic acid-copper (e.g., 30 g/liter), barium sulfide (e.g., 24 g/liter), ammonium sulfide (e.g., 24 g/liter), and sulfuric acid-copper to surfaces of the intermediate structure of FIG. 21B. The mixture may be applied, for example, at a temperature of 45° C. for 4 to 30 minutes. Another wet etch mixture may include, for example, sulfuric acid (e.g., 95 g/liter) sodium methyl triethoxysilane (e.g., 3.5 g/liter), zinc sulfide (e.g., 5 g/liter) copper sulfate aqueous solution (0.15 g/liter), and sodium chloride (e.g., 15 mg/liter). Various other wet chemical etch processes may be applied to roughen the surface of the intermediate structures of FIGS. 21B and 21C.

FIG. 21D is vertical cross-sectional view of a further intermediate structure that may be used in the formation of a semiconductor structure having a capping layer 1502, according to various embodiments. The intermediate structure of FIG. 21D may be formed by forming a seed layer 1614 over the roughened surface of the intermediate structure of FIG. 21C. The seed layer 1614 may be formed, for example, by sputtering. A sputtering process may introduce a flux of material to the surface of the intermediate structure, as indicated schematically by the arrows 2104. As mentioned above, the seed layer 1614 may include one or more of stainless steel, TiCu, TiW, TiN, and TaN.

FIG. 21E is vertical cross-sectional view of a semiconductor structure having a capping layer 1502, according to various embodiments. The semiconductor structure of FIG. 21E may be similar to the semiconductor structures of FIGS. 15A to 16B. The capping layer 1502 may include the seed layer 1614 (e.g., see FIG. 16C) that may be formed on the intermediate structure of FIG. 21D. The capping layer 1502 may further include a bulk layer 1616 (e.g., see FIG. 16C and related description, above) formed over the seed layer 1614. The bulk layer 1616 may include one or more of stainless steel, copper, nickel, tungsten, aluminum, magnalium, titanium, silver, and gold. The bulk layer may further be formed by an electroplating process. A further sputtering process may be performed to form a finish layer 1618 (e.g., see FIG. 16C) over the bulk layer 1616. The finish layer 1618 may include one or more of stainless steel, TiCu, TiW, TiN, and TaN. The seed layer 1614 and the finish layer 1618 may each have a thickness in a range from approximately 0.1 microns to approximately 0.3 microns. The bulk layer 1616 may have a thickness in a range from approximately 0.5 microns to approximately 2,000 microns. Various other materials and thicknesses may be used for the seed layer 1614, the bulk layer 1616, and the finish layer 1618.

Additional embodiments may omit the one or more of the seed layer 1614 and the finish layer 1618. Other embodiments may include a capping layer 1502 having greater numbers of layers. As described above with reference to FIGS. 17A to 18B, the capping layer 1502 may be configured to only cover certain portions of the fan-out package 500. Such structures may be formed by first forming a patterned masking structure (not shown) over the intermediate structure of FIG. 21D. The patterned masking structure may be formed by depositing and patterning a photoresist using optical lithography techniques. For example, the structure of FIGS. 18A and 18B may be formed by forming a patterned mask that covers the first semiconductor die 302 while leaving the rest of the structure (e.g., including surfaces of the second semiconductor dies 304, the molding compound die frame 502, the interposer 102, package side underfill material portions 730, and the packaging substrate 706) exposed. The capping layer 1502 may then be formed by depositing (e.g., by electroplating) a material over the exposed surfaces.

FIGS. 22A to 22J are vertical cross-sectional views of respective intermediate structures that may be used in the formation of a fan-out package 500 (e.g., see FIGS. 20A and 20B) having a capping layer 1502, and FIG. 22K is a vertical cross-sectional view of a fan-out package 500 having the capping layer 1502, according to various embodiments. As shown in FIG. 22A, a plurality of intermediate structures 2201 may be formed on a first carrier substrate 2202, as described in greater detail with reference to FIGS. 1A to 5B, above. The intermediate structures 2201 may include a first semiconductor die 302 and two or more second semiconductor dies 304 attached to an interposer 102. The intermediate structures 2201 may further include a die-side underfill material portion 402 and a molding compound die frame 502. A dicing saw 2204 may then be used to cut channels 2206 between neighboring intermediate structures 2201 without completely separating (i.e., dicing) the intermediate structures 2201.

FIG. 22B is vertical cross-sectional view of a further intermediate structure that may be used in the formation of a fan-out package 500 having a capping layer 1502, according to various embodiments. The intermediate structure of FIG. 22B may be formed by performing a surface roughening process on the intermediate structure of FIG. 22A. For example, a wet or dry roughening process may be performed, as described in greater detail with reference to FIG. 21C, above. As seed layer 1614 may then be grown over the roughened surface of the intermediate structure of FIG. 22B to thereby form the intermediate structure of FIG. 22C. As shown, the seed layer 1614 may be formed over exposed surfaces of the intermediate structure of FIG. 22B, including within the channels 2206 that separate the intermediate structures 2201 (e.g., see FIG. 22A). In this regard, the seed layer 1614 may be formed over surfaces of the first semiconductor die 302, the second semiconductor dies 304, the die-side underfill material portion 402, and the molding compound die frame 502 as shown, for example, in FIG. 22C. Also as shown, the seed layer 1614 may form over surfaces of the channels 2206 to thereby form portions of the seed layer 1614 on side surfaces of the molding compound die frame 502 and the interposers 102.

FIG. 22D is vertical cross-sectional view of a further intermediate structure that may be used in the formation of a fan-out package 500 having a capping layer 1502, according to various embodiments. In this regard, a blanket layer 1616L of material may be deposited over the seed layer 1614. The blanket layer 1616L may be formed by an electrodeposition process and may include one or more of stainless steel, copper, nickel, tungsten, aluminum, magnalium, titanium, silver, and gold. Other embodiments may include various other materials depositing using an electrodeposition process or by other deposition processes. As shown, the blanket layer 1616L may be deposited over all exposed surfaces of the seed layer 1614 of FIG. 22C including within the channels 2206. The blanket layer 1616L may then be planarized to form the capping layer 1502 as shown, for example, in FIG. 22E. For example, the blanket layer 1616L may be planarized using a chemical mechanical planarization process or other planarization process. The resulting capping layer 1502 may thereby include a two layer structure including the seed layer 1614 and the bulk layer 1616 (e.g., see FIG. 16C and related description, above). A further sputtering process may be performed (not shown) to further generate a finish layer 1618 (e.g., see FIG. 16C). As shown in FIG. 22E, the capping layer 1502 covers top and side surfaces of the underlying structures.

FIG. 22F is vertical cross-sectional view of a further intermediate structure that may be used in the formation of a fan-out package 500 having a capping layer 1502, according to various embodiments. As shown, the intermediate structure of FIG. 22F may be formed by attaching a second carrier substrate 2208 over the intermediate structure of FIG. 22E. The second carrier substrate 2208 may be removably attached to the intermediate structure of FIG. 22E with an adhesive layer 2210. The first carrier substrate 2202 may then be removed as shown in FIG. 22G, and described in greater detail with reference to FIG. 6, above.

Removing the first carrier substrate 2202 thereby exposes a surface of the interposer 102 on which conductive bump structures may be formed. For example, interposer bonding pads 702 and second solder material portions 704 may be formed on the interposer 102 as shown, for example, in FIG. 22H, and described in greater detail with reference to FIG. 7, above. The second carrier substrate 2208 may then be removed as shown, for example, in FIG. 22I, and described in greater detail with reference to FIG. 8, above. The resulting structure may then be mounted to a dicing frame 2216. A dicing saw 2204 may then be used to cut a plurality of individual, stand-alone, fan-out packages 500 that each include a capping layer as shown, for example, in FIG. 22K. The fan-out package 500 of FIG. 22K may be similar to the fan-out package 500 illustrated, for example, in FIG. 20A and described in greater detail, above.

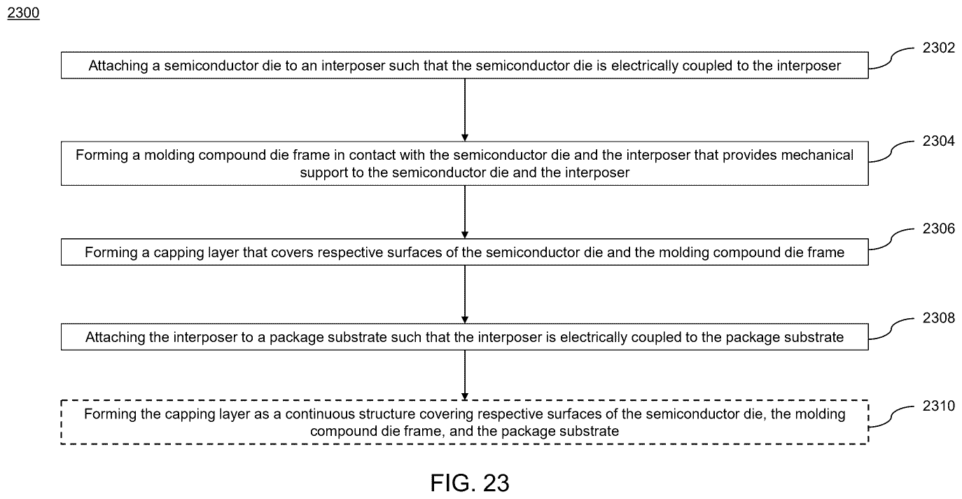

FIG. 23 is a flowchart illustrating operations of a method 2300 of forming a semiconductor structure (e.g., see FIGS. 15A to 20B, 21E, and 22K) having a capping layer 1502, according to various embodiments. In operation 2302, the method 2300 may include attaching a semiconductor die (302, 304) to an interposer 102 such that the semiconductor die is electrically coupled to the interposer (e.g., see FIG. 3A and related description, above). In operation 2304, the method 2300 may include forming a molding compound die frame 502 (e.g., see FIG. 10A) in contact with the semiconductor die (302, 304) and the interposer 102 that provides mechanical support to the semiconductor die (302, 304) and the interposer 102. In operation 2306, the method 2300 may include forming a capping layer 1502 (e.g., see FIGS. 15A to 20B, 21E, and 22K) that covers respective surfaces of the semiconductor die (302, 304, 305) and the molding compound die frame 502. In operation 2308, the method 2300 may further include attaching the interposer 102 to a packaging substrate 706 such that the interposer 102 is electrically coupled to the packaging substrate 706 (e.g., see FIGS. 12 and 21B and related description, above).

In optional operation 2310, the method 2300 may further include forming the capping layer 1502 as a continuous structure covering respective surfaces of the semiconductor die (302, 304, 305), the molding compound die frame 502, and the packaging substrate 706 (e.g., see FIGS. 15A, 16A, 19A, and 21E). The method 2300 may further include forming the capping layer 1502 as a continuous structure (e.g., see FIGS. 15A, 16A, 19A, 20A, and 21E) that covers respective surfaces of the semiconductor die (302, 304, 305), the molding compound die frame 502, and the interposer 102.

The method 2300 may further include performing an electroplating process (e.g., see FIGS. 21E, 22D, and related description, above) to deposit one or more of stainless steel, copper, nickel, tungsten, aluminum, magnalium, titanium, silver, and gold to form a bulk layer 1616 of the capping layer 1502. The method 2300 may further include performing a sputtering process (e.g., see FIGS. 21D and 22C) to deposit one or more of stainless steel, TiCu, TiW, TiN, and TaN to form a seed layer 1614 of the capping layer 1502. Further, as described above, the seed layer 1614 may be formed before the bulk layer 1616 is formed.

Referring to all drawings and according to various embodiments of the present disclosure, a semiconductor structure (e.g., see FIGS. 15A to 20B, 21E, and 22K) is provided. The semiconductor structure may include an interposer 102; a first semiconductor die 302 electrically coupled to the interposer 102; a packaging substrate 706 electrically coupled to the interposer 102; and a capping layer 1502 covering one or more of a first surface of the first semiconductor die 302 and a second surface of the packaging substrate 706. The capping layer 1502 is formed over a top surface and sidewalls of the first semiconductor die 302 and a top surface of the packaging substrate 706 (e.g., see FIGS. 15A, 16A, 19A, and 21E). In certain embodiments, the capping layer 1502 may be formed only on the first surface of the first semiconductor die 302 (i.e., not formed over the packaging substrate 706; see FIGS. 17A and 20A). In further embodiments, the semiconductor structure may include a second semiconductor die 304, such that the capping layer 1502 covers a surface of only one of the first semiconductor die 302 and the second semiconductor die 304 (e.g., see FIGS. 18A and 18B).

In certain embodiments, the capping layer 1502 may cover respective surfaces of both the first semiconductor die 302 and the second semiconductor die 304, such that a thickness of the capping layer 1502 may be greater over one of the first semiconductor die 302 and the second semiconductor die 302 than it is over the other of the first semiconductor die 302 and the second semiconductor die 304 (e.g., see FIGS. 16A, 18A, and 18B and related description above). In further embodiments, the semiconductor structure may include a molding compound die frame 502, and the capping layer 1502 may be a continuous structure covering a top surface of the first semiconductor die 302, a side surface of the molding compound die frame 502, and a side surface of the packaging substrate 706 (e.g., see FIGS. 15A, 16A, 19A and 21E).

In certain embodiments, the capping layer 1502 may include one or more of stainless steel, copper, nickel, tungsten, aluminum, magnalium, titanium, silver, and gold. Further, the capping layer 1502 may include a seed layer 1614 and a bulk layer 1616 (e.g., see FIG. 16C). The seed layer 1614 may include one or more of stainless steel, TiCu, TiW, TiN, and TaN, and the bulk layer 1616 may include one or more of stainless steel, copper, nickel, tungsten, aluminum, magnalium, titanium, silver, and gold. In some embodiments, the capping layer 1502 may further include a finish layer 1618 that includes one or more of stainless steel, TiCu, TiW, TiN, and TaN.

The packaging substrate 706 may further include a pinning structure 1902 (e.g., see FIGS. 19A and 19B) that may be formed as a plated through hole that provides mechanical stability to the packaging substrate 706. In this regard, the package substrate may include a dielectric layer 1908 formed on a top surface of the package substrate 706 and the pinning structures 1902 may formed as plated through holes protruding from the dielectric layer 1908. Further, a top surface of the pinning structure 1902 may be covered by a portion of the capping layer 1502 (e.g., see FIG. 19A). The capping layer 1502 may have a thickness in a first range from approximately 0.001 mm to approximately 10 mm (e.g., see FIG. 16A and related description). Further, the capping layer 1502 may be formed over a portion of an area of the one or more of the first semiconductor die 302 and the packaging substrate 706 that is in a second range from approximately 0.1% to approximately 100% of the area of the one or more of the first semiconductor die 302 and the packaging substrate 706 (e.g., see FIGS. 18A and 18B and related description).

In a further embodiment, a semiconductor structure may be provided that includes an interposer 102; a semiconductor die (302, 304) electrically coupled to the interposer 102; a molding compound die frame 502; and a capping layer 1502 that forms a continuous structure covering respective surfaces of the semiconductor die (302, 304), the molding compound die frame 502, and the interposer 102 (e.g., see FIGS. 20A, 20B, and related description). As described above, capping layer 1502 may include one or more of stainless steel, copper, nickel, tungsten, aluminum, magnalium, titanium, silver, and gold. The capping layer 1502 may further include a seed layer 1614 and a bulk layer 1616. The seed layer 1614 may include one or more of stainless steel, TiCu, TiW, TiN, and TaN, and the bulk layer 1616 may include one or more of stainless steel, copper, nickel, tungsten, aluminum, magnalium, titanium, silver, and gold.

The disclosed embodiments provide advantages over existing semiconductor structures by providing a capping layer 1502 that acts to mitigate the occurrence of cracking, delamination, and other mechanical degradation that may otherwise occur due to a mismatch between thermal expansion coefficients of various components of the semiconductor structure. In this regard, the material properties (e.g., thermal expansion coefficient) of the capping layer 1502 may be chosen such that, during thermal cycling, the thermal stresses/strains induced in a fan-out package 500 and packaging substrate 706 may be counteracted (e.g., canceled, balanced, etc.) by corresponding thermal stresses generated by the capping layer 1502.

The foregoing outlines features of several embodiments so that those skilled in the art may better understand the aspects of this disclosure. Those skilled in the art should appreciate that they may readily use this disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of this disclosure.

What is claimed is:

1. A semiconductor structure comprising:
an interposer;
a first semiconductor die electrically coupled to the interposer;
a packaging substrate electrically coupled to the interposer; and
a capping layer covering one or more of a first surface of the first semiconductor die and a second surface of the packaging substrate.

2. The semiconductor structure of claim 1, wherein the capping layer is formed over a top surface and sidewalls of the first semiconductor die and a top surface of the packaging substrate.

3. The semiconductor structure of claim 1, wherein the capping layer is formed only on the first surface of the first semiconductor die.

4. The semiconductor structure of claim 1, further comprising a second semiconductor die,
wherein the capping layer covers a surface of only one of the first semiconductor die and the second semiconductor die.

5. The semiconductor structure of claim 1, further comprising a second semiconductor die,
wherein the capping layer covers respective surfaces of both the first semiconductor die and the second semiconductor die, and
wherein a thickness of the capping layer is greater over one of the first semiconductor die and the second semiconductor die than it is over the other of the first semiconductor die and the second semiconductor die.

6. The semiconductor structure of claim 1, further comprising:
a molding compound die frame,
wherein the capping layer is a continuous structure covering a top surface of the first semiconductor die, a side surface of the molding compound die frame, and a side surface of the packaging substrate.

7. The semiconductor structure of claim 1, wherein the capping layer comprises one or more of stainless steel, copper, nickel, tungsten, aluminum, magnalium, titanium, silver, and gold.

8. The semiconductor structure of claim 1, wherein the capping layer comprises a seed layer and a bulk layer.

9. The semiconductor structure of claim 8, wherein the seed layer comprises one or more of stainless steel, TiCu, TiW, TiN, and TaN, and
wherein the bulk layer comprises one or more of stainless steel, copper, nickel, tungsten, aluminum, magnalium, titanium, silver, and gold.

10. The semiconductor structure of claim 8, wherein the capping layer further comprises a finish layer comprising one or more of stainless steel, TiCu, TiW, TiN, and TaN.

11. The semiconductor structure of claim 1, wherein the packaging substrate further comprises a dielectric layer on a top surface of the package substrate and a pinning structure that is formed as a plated through hole protruding from the dielectric layer, and
wherein a top surface of the pinning structure is covered by a portion of the capping layer.

12. The semiconductor structure of claim 1, wherein the capping layer has a thickness in a first range from approximately 0.001 mm to approximately 10 mm, and wherein the capping layer is formed over a portion of an area of the one or more of the first semiconductor die and the packaging substrate that is in a second range from approximately 0.1% to approximately 100% of the area of the one or more of the first semiconductor die and the packaging substrate.

13. A semiconductor structure comprising:
an interposer;
a semiconductor die electrically coupled to the interposer;
a molding compound die frame; and
a capping layer that forms a continuous structure covering a top surface of the semiconductor die, a side surface of the molding compound die frame, and a side surface of the interposer.

14. The semiconductor structure of claim 13, wherein the capping layer comprises one or more of stainless steel, copper, nickel, tungsten, aluminum, magnalium, titanium, silver, and gold.

15. The semiconductor structure of claim 13, wherein the capping layer comprises a seed layer and a bulk layer,
wherein the seed layer comprises one or more of stainless steel, TiCu, TiW, TiN, and TaN, and
wherein the bulk layer comprises one or more of stainless steel, copper, nickel, tungsten, aluminum, magnalium, titanium, silver, and gold.

16. A semiconductor structure comprising:
an interposer;
a system on chip (SOC) die coupled to the interposer;
at least one high bandwidth memory (HBM) die coupled to the interposer; and
a capping layer covering the SOC die and the at least one HBM die.

17. The semiconductor structure of claim 16, wherein the at least one HBM die comprises a vertical stack of static random access memory dies that are interconnected to one another through microbumps and are laterally surrounded by an epoxy molding material enclosure frame.

18. The semiconductor structure of claim 16, wherein the capping layer forms a continuous structure covering top surfaces of the SOC die and the HBM die, a side surface of a molding compound die frame, and a side surface of the interposer.

19. The semiconductor structure of claim 16, wherein the capping layer is formed only on top surfaces of the SOC die and the HBM die.

20. The semiconductor structure of claim 16, further comprising a packaging substrate electrically coupled to the interposer, wherein the capping layer further covers at least a portion of the packaging substrate.
